(19) United States
(12) Patent Application Publication
(10) Pub. No.: US 2026/0282675 A1
(43) Pub. Date: Sep. 17, 2026

(54) DISPLAY DEVICE AND ELECTRONIC DEVICE INCLUDING THE SAME

(71) Applicant: Samsung Display Co., Ltd., Yongin-Si (KR)

(72) Inventors: Dong Hee SHIN, Yongin-si (KR); Hyeong Seok KIM, Yongin-si (KR); Yun Mi KIM, Yongin-si (KR); Do Yeong PARK, Yongin-si (KR)

(21) Appl. No.: 19/386,256

(22) Filed: Nov. 12, 2025

(30) Foreign Application Priority Data
Mar. 11, 2025 (KR) 10-2025-0031552

(51) Int. Cl. H10K 59/131; H10K 59/121; H10K 59/122

(52) U.S. Cl. CPC H10K 59/131; H10K 59/1213; H10K 59/122

(57) ABSTRACT

Provided a display device comprises a substrate comprising a display area in which emission areas are arranged; a circuit layer located on the substrate; and an element layer located on the circuit layer. The element layer comprises light emitting elements arranged in the emission areas. The circuit layer comprises a first power line that extends in a first direction, light emitting pixel drivers that receive a first power from the first power line and respectively transmit a driving current to the light emitting elements, the light emitting pixel drivers including a first light emitting pixel driver and a second light emitting pixel driver that are adjacent to each other in a second direction that crosses the first direction; and a power connection transistor electrically connected to the first light emitting pixel driver, the second light emitting pixel driver, and the first power line.

### CROSS-REFERENCE TO RELATED APPLICATION

This application claims priority from Korean Patent Application No. 10-2025-0031552 filed on Mar. 11, 2025 in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to a display device and an electronic device including the same.

### 2. Description of the Related Art

In today's information-oriented society, demands placed on display devices to display images in various ways is increasing. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have superior performance in power consumption, response speed, luminous efficiency, luminance, and wide viewing angle compared to other display devices.

In the display device, a display surface from which light is emitted may include a display area in which an image is displayed, and a non-display area around the display area. Emission areas emitting light with respective luminances and colors may be arranged in the display area.

### SUMMARY

The display device may include light emitting pixel drivers that transmit a driving current to light emitting elements.

As the width of the light emitting pixel drivers decreases, the number of the light emitting pixel drivers that may be located in the display area may increase, which may be advantageous for achieving high resolution of the display device.

In view of the foregoing, aspects of the present disclosure provide a display device and an electronic device including the same, which may be advantageous for achieving high resolution because the width of the light emitting pixel drivers may be reduced.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprises a substrate comprising a display area in which emission areas are arranged; a circuit layer located on the substrate; and an element layer located on the circuit layer. The element layer comprises light emitting elements arranged in the emission areas. The circuit layer comprises a first power line that extends in a first direction; light emitting pixel drivers that receive a first power from the first power line and respectively transmit a driving current to the light emitting elements, the light emitting pixel drivers including a first light emitting pixel driver and a second light emitting pixel driver that are adjacent to each other in a second direction that crosses the first direction; and a power connection transistor electrically connected to the first light emitting pixel driver, the second light emitting pixel driver, and the first power line.

Each of the light emitting pixel drivers comprises a first transistor electrically connected to a first node and generating the driving current. The power connection transistor is electrically connected to the first transistor of the first light emitting pixel driver and the first transistor of the second light emitting pixel driver.

The circuit layer further comprises an auxiliary connection portion extending in the second direction. The power connection transistor is electrically connected to the first transistor of the first light emitting pixel driver and the first transistor of the second light emitting pixel driver through the auxiliary connection portion.

The circuit layer comprises a first semiconductor layer located on the substrate; a first gate insulating layer covering the first semiconductor layer; a first gate conductive layer located on the first gate insulating layer; a second gate insulating layer covering the first gate conductive layer; a second gate conductive layer located on the second gate insulating layer; a first interlayer insulating layer covering the second gate conductive layer; and a second semiconductor layer located on the first interlayer insulating layer. Each of the first transistor and the power connection transistor comprises a gate electrode, a channel portion overlapping the gate electrode, a first electrode connected to one side of the channel portion, and a second electrode connected to the other side of the channel portion. The channel portion, the first electrode, and the second electrode of the power connection transistor are located in the first semiconductor layer. The channel portion, the first electrode and the second electrode of the first transistor are located in the second semiconductor layer. The auxiliary connection portion is located in the second semiconductor layer and connected to the first electrode of the first transistor of the first light emitting pixel driver and the first electrode of the first transistor of the second light emitting pixel driver.

The light emitting pixel drivers comprise a third light emitting pixel driver and a fourth light emitting pixel driver that are positioned adjacent to the first light emitting pixel driver and the second light emitting pixel driver in the first direction, respectively. The power connection transistor is electrically connected to the first transistor of the third light emitting pixel driver and the first transistor of the fourth light emitting pixel driver.

With respect to a boundary between the first light emitting pixel driver and the third light emitting pixel driver, the second semiconductor layer of the third light emitting pixel driver is symmetrical with the second semiconductor layer of the first light emitting pixel driver. With respect to a boundary between the second light emitting pixel driver and the fourth light emitting pixel driver, the second semiconductor layer of the fourth light emitting pixel driver is symmetrical with the second semiconductor layer of the second light emitting pixel driver. The auxiliary connection portion is further connected to the first electrode of the first transistor of the third light emitting pixel driver and the first electrode of the first transistor of the fourth light emitting pixel driver.

The display area further comprises a non-emission area located between the emission areas. The non-emission area comprises a light transmitting area that transmits light. The power connection transistor is adjacent to a boundary between the first light emitting pixel driver and the second light emitting pixel driver in the second direction. The light transmitting area is adjacent to a boundary between the third light emitting pixel driver and the fourth light emitting pixel driver in the second direction and adjacent to the power connection transistor in the first direction. The auxiliary connection portion is located between the power connection transistor and the light transmitting area in the first direction.

The element layer comprises an anode electrode located in each of the emission areas; a pixel defining layer located in the non-emission area and covering an edge of the anode electrode; a light emitting layer located on the anode electrode; and a cathode electrode located on the pixel defining layer and the light emitting layer. Each of the light emitting elements has a structure in which the light emitting layer is located between the anode electrode and the cathode electrode. The pixel defining layer comprises a first pixel defining layer containing a material that blocks or absorbs light; and a first light transmission hole formed in the first pixel defining layer and overlapping the light transmitting area in a third direction perpendicular to the first direction and the second direction.

The display device further comprises an encapsulation layer covering the element layer; and a color filter layer located on the encapsulation layer. The color filter layer comprises a filter portion located in each of the emission areas and transmitting some of light emitted from the element layer; a light blocking portion located in the non-emission area; and a second light transmission hole formed in the light blocking portion and overlapping the light transmitting area in the third direction.

The circuit layer further comprises a third gate insulating layer covering the second semiconductor layer; a third gate conductive layer disposed on the third gate insulating layer; a second interlayer insulating layer covering the third gate conductive layer; a first source-drain conductive layer located on the second interlayer insulating layer; a first planarization layer covering the first source-drain conductive layer; a second source-drain conductive layer located on the first planarization layer; and a second planarization layer covering the second source-drain conductive layer. The first power line is located on the first gate conductive layer. The auxiliary connection portion is located in the second semiconductor layer. The first electrode of the power connection transistor is electrically connected to the first power line through a first power connection electrode. The second electrode of the power connection transistor is electrically connected to the auxiliary connection portion through a second power connection electrode. The first power connection electrode and the second power connection electrode are located in the first source-drain conductive layer.

The light transmitting area does not overlap the first semiconductor layer, the first gate conductive layer, the second gate conductive layer, the second semiconductor layer, the third gate conductive layer, the first source-drain conductive layer, and the second source-drain conductive layer in the third direction.

Each of the light emitting pixel drivers comprises a second transistor electrically connected between a data line that transmits a data signal and a gate electrode of the first transistor; a third transistor electrically connected between a reference voltage line that transmits a reference voltage and the gate electrode of the first transistor; a fourth transistor electrically connected between an initialization voltage line that transmits an initialization voltage and a second node; a fifth transistor electrically connected between the first node and the second node; a first capacitor electrically connected between the gate electrode of the first transistor and the first node; and a second capacitor electrically connected to the first node. The first node is electrically connected to a second electrode of the first transistor. The second node is electrically connected to one of the light emitting elements. A gate electrode of the second transistor is electrically connected to a scan write line that transmits a scan write signal. A gate electrode of the third transistor is electrically connected to a reset control line that transmits a reset control signal. A gate electrode of the fourth transistor is electrically connected to an initialization control line that transmits an initialization control signal. A gate electrode of the power connection transistor is electrically connected to a first emission control line that transmits a first emission control signal. A gate electrode of the fifth transistor is electrically connected to a second emission control line that transmits a second emission control signal. Each of the reference voltage line, the reset control line, the first emission control line, the second emission control line, the initialization control line, and the initialization voltage line extends in the first direction. Some of the reference voltage line, the reset control line, the first emission control line, the second emission control line, the initialization control line and the initialization voltage line intersect the first light emitting pixel driver, and some others intersect the second light emitting pixel driver.

The third transistor of each of the first light emitting pixel driver and the second light emitting pixel driver is electrically connected to a reference voltage line and a reset control line that intersect the first light emitting pixel driver. The fourth transistor of each of the first light emitting pixel driver and the second light emitting pixel driver is electrically connected to an initialization control line and an initialization voltage line that intersect the second light emitting pixel driver. The fifth transistor of the first light emitting pixel driver and the fifth transistor of the second light emitting pixel driver are electrically connected to the second emission control line that intersects the second light emitting pixel driver. The third transistor of the second light emitting pixel driver is adjacent to the third transistor of the first light emitting pixel driver in the first direction. The fourth transistor of the first light emitting pixel driver is adjacent to the fourth transistor of the second light emitting pixel driver in the first direction. The fifth transistor of the first light emitting pixel driver is adjacent to the fifth transistor of the second light emitting pixel driver in the first direction.

According to an aspect of the present disclosure, there is provided an electronic device comprises a display device displaying an image; a memory storing an application; a processor executing the application and transmitting an image data signal and an input control signal to the display device; and a power module transmitting power to the display device. The display device comprises a substrate comprising a display area in which emission areas are arranged; a circuit layer located on the substrate; and an element layer located on the circuit layer. The element layer comprises light emitting elements arranged in the emission areas. The circuit layer comprises a first power line that extends in a first direction, light emitting pixel drivers that receive a first power from the first power line and respectively transmit a driving current to the light emitting elements, the light emitting pixel drivers including a first light emitting pixel driver and a second light emitting pixel driver that are adjacent to each other in a second direction that crosses the first direction; and a power connection transistor electrically connected to the first light emitting pixel driver, the second light emitting pixel driver, and the first power line.

The circuit layer further comprises an auxiliary connection portion extending in the second direction. Each of the light emitting pixel drivers comprises a first transistor electrically connected to a first node and generating the driving current. The power connection transistor is electrically connected to the first transistor of the first light emitting pixel driver and the first transistor of the second light emitting pixel driver through the auxiliary connection portion.

The circuit layer comprises a first semiconductor layer located on the substrate; a first gate insulating layer covering the first semiconductor layer; a first gate conductive layer located on the first gate insulating layer; a second gate insulating layer covering the first gate conductive layer; a second gate conductive layer located on the second gate insulating layer; a first interlayer insulating layer covering the second gate conductive layer; and a second semiconductor layer located on the first interlayer insulating layer. Each of the first transistor and the power connection transistor comprises a gate electrode, a channel portion overlapping the gate electrode, a first electrode connected to one side of the channel portion, and a second electrode connected to the other side of the channel portion. The channel portion, the first electrode, and the second electrode of the power connection transistor are located in the first semiconductor layer. The channel portion, the first electrode and the second electrode of the first transistor are located in the second semiconductor layer. The auxiliary connection portion is located in the second semiconductor layer and connected to the first electrode of the first transistor of the first light emitting pixel driver and the first electrode of the first transistor of the second light emitting pixel driver.

The light emitting pixel drivers comprise a third light emitting pixel driver and a fourth light emitting pixel driver that are positioned adjacent to the first light emitting pixel driver and the second light emitting pixel driver in the first direction, respectively. With respect to a boundary between the first light emitting pixel driver and the third light emitting pixel driver, the second semiconductor layer of the third light emitting pixel driver is symmetrical with the second semiconductor layer of the first light emitting pixel driver. With respect to a boundary between the second light emitting pixel driver and the fourth light emitting pixel driver, the second semiconductor layer of the fourth light emitting pixel driver is symmetrical with the second semiconductor layer of the second light emitting pixel driver.

The auxiliary connection portion is further connected to the first electrode of the first transistor of the third light emitting pixel driver and the first electrode of the first transistor of the fourth light emitting pixel driver.

The display area further comprises a non-emission area located between the emission areas. The non-emission area comprises a light transmitting area that transmits light. The power connection transistor is adjacent to a boundary between the first light emitting pixel driver and the second light emitting pixel driver in the second direction. The light transmitting area is adjacent to a boundary between the third light emitting pixel driver and the fourth light emitting pixel driver in the second direction. The auxiliary connection portion is located between the power connection transistor and the light transmitting area in the first direction.

The display device further comprises an encapsulation layer covering the element layer; and a color filter layer located on the encapsulation layer. The element layer comprises

an anode electrode located in each of the emission areas; and a pixel defining layer located in the non-emission area and covering an edge of the anode electrode. The pixel defining layer comprises a first pixel defining layer containing a material that blocks or absorbs light; and a first light transmission hole formed in the first pixel defining layer and overlapping the light transmitting area in a third direction perpendicular to the first direction and the second direction. The color filter layer comprises a filter portion located in each of the emission areas and transmitting a part of light emitted from the element layer; a light blocking portion located in the non-emission area; and a second light transmission hole formed in the light blocking portion and overlapping the light transmitting area in the third direction.

The display device according to one embodiment includes a circuit layer located on a substrate, and an element layer located on the circuit layer. The element layer includes light emitting elements located in to the emission areas. The circuit layer may include light emitting pixel drivers that respectively transmit a driving current to the light emitting elements, a first power line that transmits a first power to the light emitting pixel drivers and extends in a first direction, and a power connection transistor that is electrically connected between the first power line and a first light emitting pixel driver and a second light emitting pixel driver adjacent to each other in a second direction among the light emitting pixel drivers.

That is, the first light emitting pixel driver and the second light emitting pixel driver may not include the respective power connection transistors, and may be electrically connected to the first power line through one power connection transistor.

In this way, the number of power connection transistors located in the display area may be reduced to a half of the number of light emitting pixel drivers. Accordingly, the width of the light emitting pixel drivers may be reduced, which may be advantageous for achieving high resolution of the display device.

According to one embodiment, the light emitting pixel drivers may include a third light emitting pixel driver and a fourth light emitting pixel driver adjacent to the first light emitting pixel driver and the second light emitting pixel driver, respectively, in the first direction.

The power connection transistor may be further electrically connected to a third light emitting pixel driver and a fourth light emitting pixel driver.

That is, four light emitting pixel drivers adjacent in the first direction and the second direction may be electrically connected to the first power line through one power connection transistor.

In this way, the number of power connection transistors located in the display area may be reduced to ¼ of the number of light emitting pixel drivers, which may be further advantageous for achieving high resolution of the display device.

According to one embodiment, the display area may include emission areas that emit light and a non-emission area located between the emission areas.

According to one embodiment, the third light emitting pixel driver and the fourth light emitting pixel driver may be electrically connected to the power connection transistor located adjacent to the boundary between the first light emitting pixel driver and the second light emitting pixel driver. Therefore, a part of the non-emission area, which is adjacent to the boundary between the third light emitting pixel driver and the fourth light emitting pixel driver and adjacent to the power connection transistor in the first direction, may be formed as a light transmitting area that transmits light.

That is, even if the number of light emitting pixel drivers is not reduced, the formation of a light path for a light sensing operation of an optical device located under the display device may become relatively easy by the light transmitting area. Therefore, the resolution and usability of the display device and the electronic device including the same may be improved.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to one embodiment;

FIG. 2 is an exploded perspective view of an electronic device according to one embodiment;

FIG. 3 is a plan view illustrating the display device of FIG. 2;

FIG. 4 is a cross-sectional view taken along line A-A′ of FIG. 3;

FIG. 5 is a schematic diagram showing part B of FIG. 3;

FIG. 6 is a block diagram showing the display device of FIG. 2;

FIG. 7 is an equivalent circuit diagram showing the light emitting pixel driver of FIG. 6;

FIG. 8 is a cross-sectional view illustrating the first transistor, the second transistor, the fifth transistor, the first capacitor, the second capacitor, and the light emitting element of FIG. 7;

FIG. 9 is a block diagram showing part C of FIG. 5 according to one embodiment;

FIG. 10 is an exploded perspective view of an electronic device according to one embodiment;

FIG. 11 is a plan view illustrating the display device of FIG. 10;

FIG. 12 is a schematic diagram illustrating part D of FIG. 10;

FIG. 13 is a block diagram showing part E of FIG. 12;

FIGS. 14, 15, 16, 17, 18, and 19 are plan views showing a part of part E of FIG. 12 according to one embodiment;

FIG. 20 is a cross-sectional view taken along line F-F′ of FIG. 19;

FIG. 21 is a block diagram of an electronic device according to one embodiment; and

FIG. 22 is schematic views of electronic devices according to various embodiments.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means a schematic cross-section is taken by cutting an object portion. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may interface a second object, either by direct contact or with a space or a third object in between. In a case in which a third object intervenes between a first and second object, the first and second objects may be understood as being indirectly interfacing one another, and still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

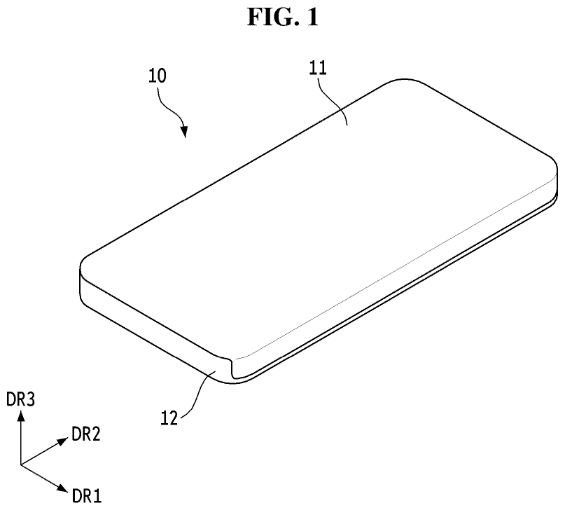

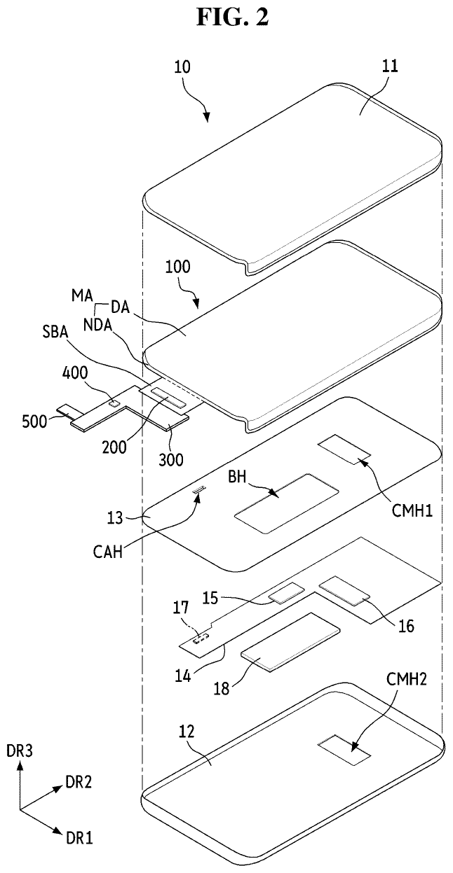

FIG. 1 is a perspective view showing an electronic device according to one embodiment. FIG. 2 is an exploded perspective view of an electronic device according to one embodiment.

Referring to FIG. 1, an electronic device 10 according to one embodiment is a device having a function of displaying an image in a display area. The electronic device 10 may provide portability. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to one embodiment is not limited to a portable electronic device, and may be a large-sized device such as a television, a laptop computer, a monitor, a billboard, and an Internet-of-Things (IoT) device.

The electronic device 10 according to one embodiment may include a cover window 11 and a lower cover 12, which are provided as a housing to protect a display device 100 (see FIG. 2).

Referring to FIG. 2, the electronic device 10 may further include the display device 100, a bracket 13, and a main circuit board 14, which are accommodated between the cover window 11 and the lower cover 12.

The display device 100 may include a main region MA including a display area DA where an image is displayed and a non-display area NDA around the display area DA, and a sub-region SBA protruding from one side of the main region MA.

The display device 100 may further include a display driving circuit 200 located in the sub-region SBA, a display circuit board 300 bonded to one side of the sub-region SBA, a touch driving circuit 400 mounted on the display circuit board 300, and a cable 500 extending from one side of the display circuit board 300.

In the present specification, a first direction DR1 may be a direction parallel to a short side of the electronic device 10 in plan view, that is, a horizontal direction of the electronic device 10. A second direction DR2 may be a direction parallel to a long side of the electronic device 10 in plan view, that is, a vertical direction of the electronic device 10. A third direction DR3 may be a thickness direction of the electronic device 10.

The electronic device 10 may have a shape that resembles a rectangle in plan view. For example, the electronic device 10 may have a rectangular shape, in plan view, having a short side in the first direction DR1 and a long side in the second direction DR2. A corner where the short side in the first direction DR1 and the long side in the second direction DR2 meet may be right-angled or rounded with a selected curvature. The planar shape of the electronic device 10 is not limited to the rectangular shape, and may be formed in another polygonal shape, a circular shape or an elliptical shape.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

That is, the cover window 11 may be located on the display device 100.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

The display device 100 may include the main region MA serving as a display surface and the sub-region SBA protruding from at least a part of one side of the main region MA.

The main region MA may include the display area DA displaying an image and the non-display area NDA that is a peripheral area of the display area DA.

The display area DA may be located in most of the main region MA. The display area DA may be located at the center of the main region MA.

In other words, each of the top, left, and right surface portions of the display device 100 may include the display area DA and the non-display area NDA.

The display area DA may be located on most of each of the top, left, and right surface portions of the display device 100.

The non-display area NDA may be located outside the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto.

Since a part of the sub-region SBA is transformed to be bent, another part of the sub-region SBA may overlap the main region MA in the third direction DR3.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

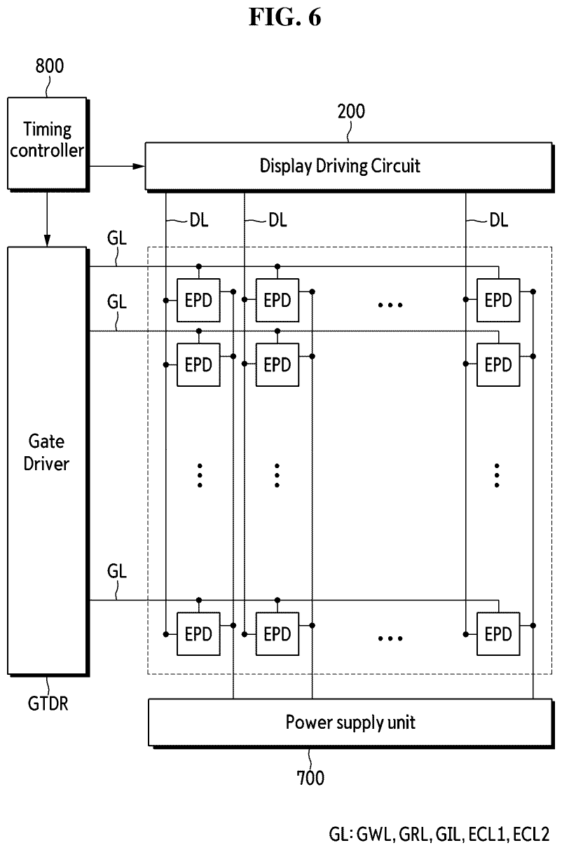

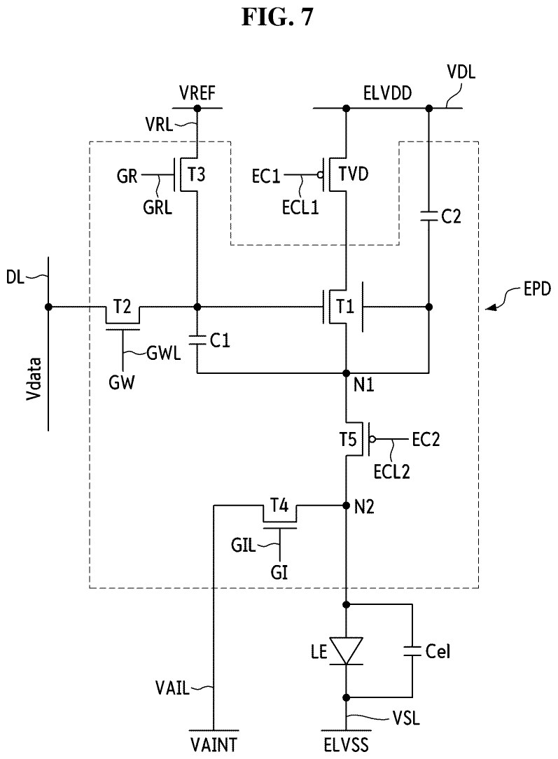

Based on control signals, power and voltages supplied through the display circuit board 300, the display driving circuit 200 may transmit a data signal Vdata (see FIG. 7) of each of light emitting pixel drivers EPD (see FIG. 6) of the display area DA to data lines DL (see FIG. 6).

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and one embodiment is not limited thereto. For example, the display driving circuit 200 may be mounted on the display circuit board 300.

According to one embodiment, the touch driving circuit 400 may be further mounted on the sub-region SBA of the display device 100.

Alternatively, as shown in FIG. 2, the touch driving circuit 400 may be mounted on the display circuit board 300.

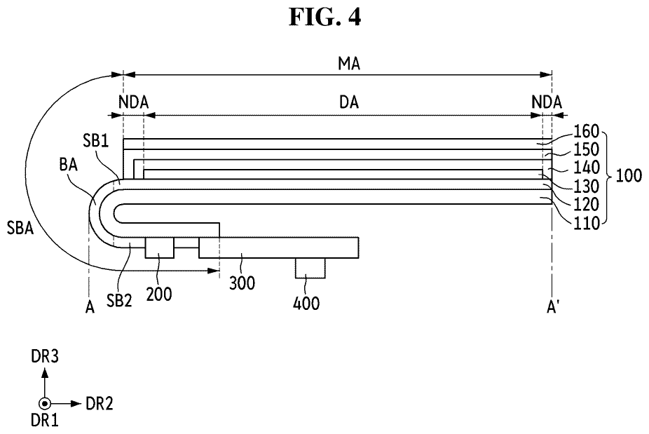

The touch driving circuit 400 may be electrically connected to a touch sensor layer 150 (see FIG. 4) of the display device 100.

As shown in FIG. 2, the bracket 13 may be located under the display device 100.

The bracket 13 may include plastic or metal. The bracket 13 may include a first camera hole CMH1 into which a camera device 16 is inserted, a battery hole BH into which a battery 18 is located, and a cable hole CAH through which the cable 500 connected to the display circuit board 300 passes.

The main circuit board 14 and the battery 18 may be located under the bracket 13.

The main circuit board 14 may be a printed circuit board or a flexible printed circuit board.

The main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or otherwise activated the circuit, and then perform an operation corresponding to the user's input. For example, the main processor 15 may perform an operation or execute an application indicated by an icon touched by the user.

The main processor 15 may be an application processor including an integrated circuit, a central processing unit, or a system chip.

The camera device 16 may process an image frame of a still image or video obtained by an image sensor in a camera mode and output it to the main processor 15.

The cable 500 having passed through the cable hole CAH of the bracket 13 may be connected to the main connector 17. Thus, the main circuit board 14 may be electrically connected to the display circuit board 300.

The battery 18 may be located so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18. The lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not limited by the illustration in FIG. 2.

Next, the display device 100 according to one embodiment will be described.

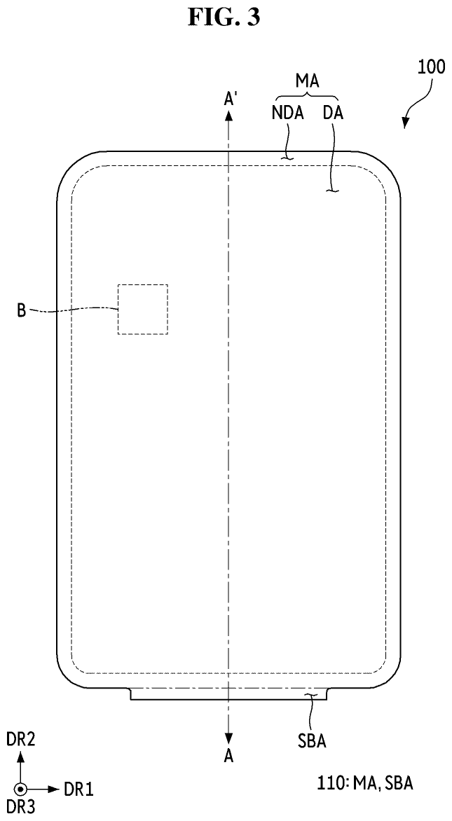

FIG. 3 is a plan view illustrating the display device of FIG. 2. FIG. 4 is a cross-sectional view taken along line A-A′ of FIG. 3.

Referring to FIGS. 3 and 4, the display device 100 according to one embodiment, which is a device for displaying a moving image or a still image, may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 3, at least one surface of the display device 100 includes the main region MA from which light for displaying an image is emitted.

The display area DA may, in plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a selected curvature or may be right-angled. The planar shape of the display area DA is not limited to a rectangular shape, and may be formed in another polygonal shape, a circular shape or an elliptical shape.

The display area DA may be located in most of the main region MA. The display area DA may be located at the center of the main region MA.

Referring to FIG. 4, the display device 100 may further include the sub-region SBA protruding in the second direction DR2 from at least a part of one side of the main region MA.

Since a part of the sub-region SBA is transformed into a bent shape, another part of the sub-region SBA may be located on the rear surface of the display device 100.

According to one embodiment, the display device 100 includes a substrate 110, a circuit layer 120 located on the substrate 110, and an element layer 130 located on the circuit layer 120.

The display device 100 may further include an encapsulation layer 140 located on the element layer 130, and a touch sensor layer 150 located on the encapsulation layer 140.

The display device 100 may further include a polarization layer 160 located on the touch sensor layer 150, in order to reduce reflection of external light.

The substrate 110 may include the main region MA corresponding to the display surface, and the sub-region SBA that extends in the second direction DR2 from at least a part of one side of the main region MA. FIG. 4 depicts the sub-region SBA in a bent state.

The main region MA of the substrate 110 may include the display area DA from which light is emitted, and the non-display area NDA located around the display area DA.

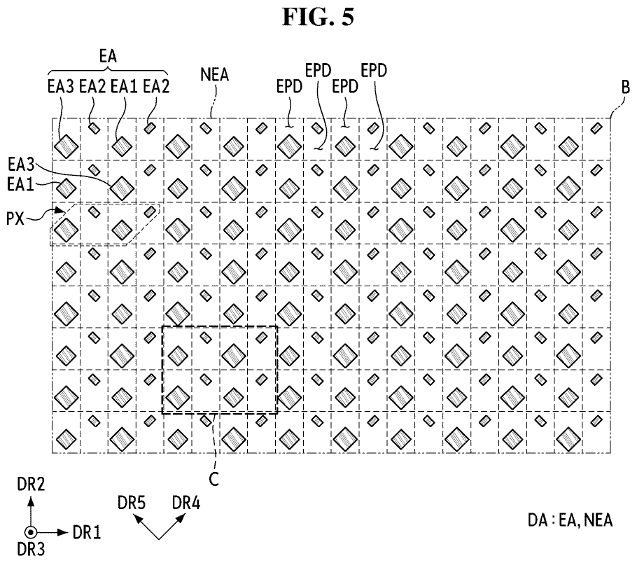

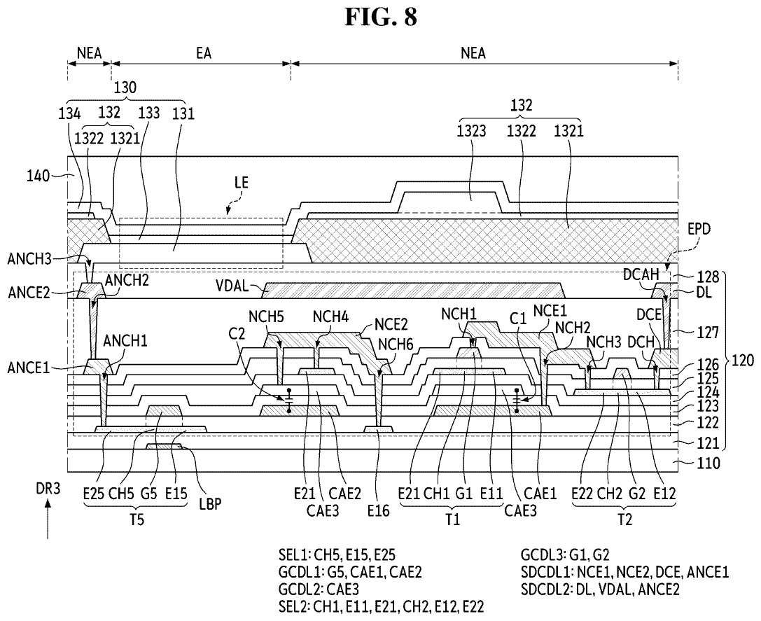

According to one embodiment, the element layer 130 may include light emitting elements LE (see FIGS. 7 and 8) respectively located in the emission areas EA (see FIG. 5).

The circuit layer 120 may include the light emitting pixel drivers EPD (see FIG. 5) electrically connected to light emitting elements LE, and the data lines DL (see FIGS. 6 and 7) that transmit the data signal Vdata (see FIG. 7) of the light emitting pixel drivers EPD (see FIG. 5).

The encapsulation layer 140 may cover the element layer 130. The encapsulation layer 140 may include a structure in which two or more inorganic layers and at least one organic layer are alternately stacked.

The touch sensor layer 150 may be located on the encapsulation layer 140 and may be disposed in the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and this is to prevent the deterioration of visibility of an image due to external light reflection.

If a part of the sub-region SBA is bent, the display driving circuit 200 mounted in the sub-region SBA, and the display circuit board 300 connected to one side of the sub-region SBA may be located under the substrate 110.

The display driving circuit 200 may be electrically connected to the data lines DL (see FIGS. 6 and 7) of the circuit layer 120. The display driving circuit 200 may transmit the data signals Vdata (see FIG. 7) of the light emitting pixel drivers EPD (see FIG. 5) through the data lines DL based on control signals and power voltages supplied from the display circuit board 300.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and one embodiment is not limited thereto. For example, the display driving circuit 200 may be mounted on the display circuit board 300.

One end of the display circuit board 300 may be attached onto pads located on one edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

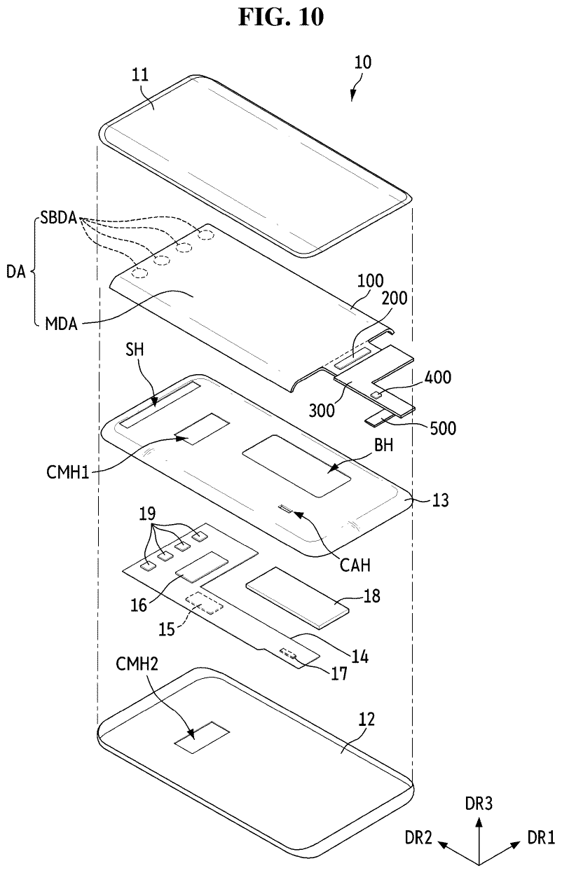

The display circuit board 300 may be connected to signal pads SPD (see FIG. 10) located on one side of the sub-region SBA.

The touch driving circuit 400 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user input is received.

A user's “touch” means that an object such as a pen or a user's finger made a direct contact with the top surface of the cover window located on the touch sensor layer. A user's “approach” means that the object such as the pen or the user's finger hovered over the top surface of the cover window without actually making contact with the top surface. Both “touch” and “approach” count as input from a user.

The touch driving circuit 400 may output touch data including the user's touch coordinates to the main processor 15 (see FIG. 2).

FIG. 5 is a schematic diagram showing part B of FIG. 3.

As shown in FIG. 5, the display area DA may include the emission areas EA from which light is emitted, and a non-emission area NEA that is a separation area between the emission areas EA and from which light is not emitted.

Each of the emission areas EA may be a unit area that emits light in a wavelength band corresponding to one color of two or more different colors with a luminance corresponding to an image signal.

Each of the emission areas EA may be arranged in a quadrilateral shape.

However, this is only an example, and the planar shape of the emission areas EA according to one embodiment is not limited to that illustrated in FIG. 5. That is, the emission areas EA may have a planar shape of a polygon such as a rectangle, a square, a hexagon, and an octagon other than a rhombus, a circle, or an ellipse.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

For example, the first wavelength band may be from about 600 nm to about 750 nm and may correspond to a red color. The second wavelength band may be from about 480 nm to about 560 nm and may correspond to a green color. The third wavelength band may be from about 370 nm to about 460 nm and may correspond to a blue color.

However, this is only an example, and the first wavelength band, the second wavelength band, and the third wavelength band according to one embodiment are not limited thereto.

Since the emission areas EA include the first emission area EA1, the second emission area EA2, and the third emission area EA3, each of unit pixels PX may be provided by a combination of one or more first emission areas EA1, one or more second emission areas EA2, and one or more third emission areas EA3 adjacent to each other among the emission areas EA.

Each of the unit pixels PX may be a unit for displaying various colors including white. That is, lights of various colors displayed by the unit pixels PX may be implemented as a mixture of lights emitted from two or more emission areas EA included in each unit pixel PX.

The third emission area EA3 may have a width greater than that of the first emission area EA1, and the first emission area EA1 may have a width greater than that of the second emission area EA2. However, this is merely an example, and the width of each of the emission areas EA is not limited to that illustrated in FIG. 5.

The first emission areas EA1 and the third emission areas EA3 may be alternately arranged in the first direction DR1 in a row, and in the second direction DR2 in a column, respectively.

The second emission area EA2 may be arranged side by side in a row extending in the first direction DR1 and in a column extending in the second direction DR2.

Rows alternate between rows of second emission areas EA2 and rows of first and third emission areas EA1, EA3. For example, odd-numbered rows may have second emission areas EA2, and even-numbered rows may have first and third emission areas EA1, EA3. Columns may also alternate between columns of second emission areas EA2 and columns that have first and third emission areas EA1, EA3 alternating. For example, odd-numbered columns may have first and third emission areas EA1, EA3, and even-numbered columns may have second emission areas EA2. Each of the second emission areas EA2 may be arranged between the first emission area EA1 and the third emission area EA3 in diagonal directions DR4 and DR5 intersecting the first direction DR1 and the second direction DR2.

For example, each of the unit pixels PX may include one or more first emission areas EA1 and one or more third emission areas EA3 adjacent to each other in the first direction DR1, and two or more second emission areas EA2 adjacent thereto in the second direction DR2. However, this is only an example, and the arrangement pattern of the emission areas EA and the components of the unit pixel PX according to one embodiment are not limited to the above description.

According to one embodiment, the circuit layer 120 (see FIG. 4) may include the light emitting pixel drivers EPD arranged in the first direction DR1 and the second direction DR2 in the display area DA.

The element layer 130 (see FIG. 4) may include light emitting elements LE (see FIGS. 7 and 8) located in the emission areas EA.

The light emitting pixel drivers EPD may respectively transmit a driving current to the light emitting elements LE (see FIGS. 7 and 8).

FIG. 6 is a block diagram showing the display device of FIG. 2.

Referring to FIG. 6, the circuit layer 120 of the display device 100 according to one embodiment may include the light emitting pixel drivers EPD electrically connected to the light emitting elements LE (see FIG. 7) arranged in the emission areas EA (see FIG. 5), and the data lines DL that transmit the data signals Vdata (see FIG. 7) to the light emitting pixel drivers EPD.

The circuit layer 120 may further include one or more gate lines GL that transmit one or more gate signals to the light emitting pixel drivers EPD.

According to one embodiment, the display device 100 may further include the display driving circuit 200 that outputs the data signals Vdata (see FIG. 7) of the light emitting pixel drivers EPD to the data lines DL to control the luminance of each of the light emitting elements LE (see FIG. 7).

According to one embodiment, the display device 100 may further include a gate driver GTDR that outputs gate signals to the gate lines GL, a power supply unit 700 that supplies power and voltages to the light emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driver GTDR.

The display driving circuit 200 may convert the image data DATA into analog data voltages and output them to the data lines DL.

The gate driver GTDR may generate gate signals in response to the scan control signal SCS and sequentially output the gate signals to gate lines GL.

The gate lines GL may include a scan write line GWL that transmits a scan write signal GW (see FIG. 7), a reset control line GRL that transmits a reset control signal GR (see FIG. 7), an initialization control line GIL that transmits an initialization control signal GI (see FIG. 7), a first emission control line ECL1 that transmits a first emission control signal EC1 (see FIG. 7), and a second emission control line ECL2 that transmits a second emission control signal EC2 (see FIG. 7).

The gate signals may have pulses that vary to a first gate level voltage or a second gate level voltage.

The power supply unit 700 may supply various power and voltages necessary for driving the light emitting pixel drivers EPD.

For example, the power supply unit 700 may supply a first power ELVDD (see FIG. 7) and a second power ELVSS (see FIG. 7) for generating a driving signal transmitted to the light emitting elements LE, a reference voltage VREF (see FIG. 7) and an initialization voltage VAINT (see FIG. 7) for initializing the light emitting elements LE (see FIG. 7).

For example, the first power ELVDD may have a voltage level higher than that of the second power ELVSS, the reference voltage VREF, and the initialization voltage VAINT.

FIG. 7 is an equivalent circuit diagram showing the light emitting pixel driver of FIG. 6.

Referring to FIG. 7, the circuit layer 120 (see FIG. 4) may include a first power line VDL for transmitting the first power ELVDD to the light emitting pixel drivers EPD, a second power line VSL for transmitting the second power ELVSS to the light emitting elements LE, a reference voltage line VRL for transmitting a reference voltage VREF to the light emitting pixel drivers EPD, and an initialization voltage line VAIL for transmitting an initialization voltage VAINT.

The light emitting elements LE of the element layer 130 (see FIG. 4) may be electrically connected between the light emitting pixel drivers EPD and a second power source ELVSS.

That is, one of the light emitting elements LE may be electrically connected between one of the light emitting pixel drivers EPD of the circuit layer 120 and the second power source ELVSS.

The second power ELVSS may be at a voltage level lower than that of the first power ELVDD.

That is, the anode electrode of the light emitting element LE may be electrically connected to the light emitting pixel driver EPD, and the cathode electrode of the light emitting element LE may be electrically connected to the second power line VSL that transmits the second power ELVSS.

A capacitor Cel connected in parallel with the light emitting element LE refers to a parasitic capacitance between the anode electrode and the cathode electrode.

The circuit layer 120 may include the scan write line GWL that transmits the scan write signal GW, the reset control line GRL that transmits the reset control signal GR, the initialization control line GIL that transmits the initialization control signal GI, the first emission control line ECL1 that transmits the first emission control signal EC1, and the second emission control line ECL2 that transmits the second emission control signal EC2.

According to one embodiment, each of the light emitting pixel drivers EPD of the circuit layer 120 may include a first transistor T1 that is electrically connected to a first node N1 and generates a driving current for driving the light emitting element LE.

According to one embodiment, the circuit layer 120 may include a power connection transistor TVD electrically connected between the light emitting pixel driver EPD and the first power line VDL.

According to one embodiment, each of the light emitting pixel drivers EPD of the circuit layer 120 may further include two or more transistors T2 to T5 electrically connected to the first transistor T1 or the light emitting element LE, and one or more capacitors C1 and C2.

That is, each of the pixel drivers EPD may further include the second transistor T2 electrically connected between the data line DL and the gate electrode of the first transistor T1, the third transistor T3 electrically connected between the reference voltage line VRL and the gate electrode of the first transistor T1, the fourth transistor T4 electrically connected between the initialization voltage line VAIL and a second node N2, the fifth transistor T5 electrically connected between the first node N1 and the second node N2, the first capacitor C1 electrically connected between the gate electrode of the first transistor T1 and the first node N1, and the second capacitor C2 electrically connected between the first node N1 and the first power line VDL.

The first node N1 may be electrically connected to the second electrode of the first transistor T1.

The second node N2 may be electrically connected to the light emitting element LE.

The second transistor T2 may be turned on by the scan write signal GW of the scan write line GWL.

When the second transistor T2 is turned on, the data signal Vdata of the data line DL may be transmitted to the gate electrode of the first transistor T1.

When the voltage difference between the gate electrode of the first transistor T1 and the second electrode of the first transistor T1 is equal to or greater than the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata.

The third transistor T3 may be turned on by the reset control signal GR of the reset control line GRL.

When the third transistor T3 is turned on, the potential of the gate electrode of the first transistor T1 may be reset to the reference voltage VREF of the reference voltage line VRL.

The fourth transistor T4 may be turned on by the initialization control signal GI of the initialization control line GIL.

When the fourth transistor T4 is turned on, the potential of the anode electrode of the light emitting element LE may be initialized to the initialization voltage VAINT of the initialization voltage line VAIL.

The first transistor T1 may be electrically connected to the first power line VDL (see FIG. 7) through the power connection transistor TVD.

The power connection transistor TVD may be turned on by the first emission control signal EC1 of the first emission control line ECL1.

When the power connection transistor TVD is turned on, the first power ELVDD of the first power line VDL may be transmitted to the first electrode of the first transistor T1.

The fifth transistor T5 may be turned on by the second emission control signal EC2 of the second emission control line ECL2.

When the fifth transistor T5 is turned on, the drain-source current of the first transistor T1, which is generated with a magnitude corresponding to the data signal Vdata, may be transmitted as a driving current to the light emitting element LE through the fifth transistor T5.

Accordingly, the light emitting element LE may emit light having a luminance corresponding to the data signal Vdata.

The first capacitor C1 may be electrically connected between the gate electrode of the first transistor T1 and the second electrode of the first transistor T1.

Accordingly, the first capacitor C1 may be charged with the data signal Vdata applied to the gate electrode of the first transistor T1, and the turn-on of the first transistor T1 may be maintained for a selected period due to the voltage charged in the first capacitor C1.

A second capacitor C2 may be electrically connected between the second electrode of the first transistor T1 and the first power line VDL.

The voltage of the first capacitor C1 may correspond to the potential difference between the gate electrode of the first transistor T1 and the second electrode of the first transistor T1, and may be changed by the data signal Vdata.

In addition, the voltage of the first capacitor C1 may be divided by the second capacitor C2. Accordingly, the potential difference between the gate electrode of the first transistor T1 and the second electrode of the first transistor may be maintained at a magnitude corresponding to the data signal Vdata.

According to one embodiment, the first transistor T1 may include a gate electrode and an additional electrode facing opposite surfaces of a channel portion.

The gate electrode of the first transistor T1 may be electrically connected to the second transistor T2.

The additional electrode of the first transistor T1 may be electrically connected to the second electrode of the first transistor T1.

Accordingly, when the data signal Vdata is applied to the gate electrode of the first transistor T1 such that the first transistor T1 is in a turned-on state, compared to a portion of the channel portion of the first transistor T1, which is adjacent to the gate electrode, the other portion of the channel portion of the first transistor T1, which is adjacent to the additional electrode, may not be activated.

Therefore, since the electron mobility in the channel portion of the first transistor T1 decreases, the slope of a current curve representing a relationship between the drain-source current and the voltage of the gate electrode of the first transistor T1 may decrease. Accordingly, a driving voltage range of the first transistor T1 may be widened, which may facilitate luminance control.

As illustrated in FIG. 7, the first transistor T1 may be an N-type MOSFET. Further, at least some of the second to fifth transistors T2 to T5 and the power connection transistor TVD may be P-type MOSFETs.

For example, the power connection transistor TVD and the fifth transistor T5 may be P-type MOSFETs, and the second transistor T2, the third transistor T3, and the fourth transistor T4 may be N-type MOSFETs.

Alternatively, the fifth transistor T5 may be a P-type MOSFET, and the second transistor T2, the third transistor T3, the fourth transistor T4, and the power connection transistor TVD may be N-type MOSFETs.

Accordingly, according to one embodiment, the circuit layer 120 may include a first semiconductor layer SEL1 (see FIG. 8) for forming a P-type MOSFET and a second semiconductor layer SEL2 (see FIG. 8) for forming an N-type MOSFET.

FIG. 8 is a cross-sectional view illustrating the first transistor, the second transistor, the fifth transistor, the first capacitor, the second capacitor, and the light emitting element of FIG. 7.

Referring to FIG. 8, the display device 100 according to one embodiment may include the substrate 110, the circuit layer 120 on the substrate 110, and the element layer 130 on the circuit layer 120.

The display device 100 may further include the encapsulation layer 140 on the element layer 130.

According to one embodiment, the circuit layer 120 may include the first semiconductor layer SEL1 located on the substrate 110, a first interlayer insulating layer 124 located on the first semiconductor layer SEL1, and the second semiconductor layer SEL2 located on the first interlayer insulating layer 124.

The circuit layer 120 may further include a first gate insulating layer 122 covering the first semiconductor layer SEL1, a first gate conductive layer GCDL1 located on the first gate insulating layer 122, a second gate insulating layer 123 covering the first gate conductive layer GCDL1, a second gate conductive layer GCDL2 located between the second gate insulating layer 123 and the first interlayer insulating layer 124, a third gate insulating layer 125 covering the second semiconductor layer SEL2, a third gate conductive layer GCDL3 located on the third gate insulating layer 125, a second interlayer insulating layer 126 covering the third gate conductive layer GCDL3, a first source-drain conductive layer SDCDL1 located on the second interlayer insulating layer 126, a first planarization layer 127 covering the first source-drain conductive layer SDCDL1, a second source-drain conductive layer SDCDL2 located on the first planarization layer 127, and a second planarization layer 128 covering the second source-drain conductive layer SDCDL2.

In other words, the circuit layer 120 may include the first semiconductor layer SEL1 located on the substrate 110, the first gate insulating layer 122 covering the first semiconductor layer SEL1, the first gate conductive layer GCDL1 located on the first gate insulating layer 122, the second gate insulating layer 123 covering the first gate conductive layer GCDL1, the second gate conductive layer GCDL2 located between the second gate insulating layer 123 and the first interlayer insulating layer 124, the first interlayer insulating layer 124 covering the second gate conductive layer GCDL2, and the second semiconductor layer SEL2 located on the first interlayer insulating layer 124. In addition, the circuit layer 120 may further include the third gate insulating layer 125 covering the second semiconductor layer SEL2, the third gate conductive layer GCDL3 located on the third gate insulating layer 125, the second interlayer insulating layer 126 covering the third gate conductive layer GCDL3, the first source-drain conductive layer SDCDL1 located on the second interlayer insulating layer 126, the first planarization layer 127 covering the first source-drain conductive layer SDCDL1, the second source-drain conductive layer SDCDL2 located on the first planarization layer 127, and the second planarization layer 128 covering the second source-drain conductive layer SDCDL2.

According to one embodiment, the circuit layer 120 may further include the buffer layer 121 covering the substrate 110. In this case, the first semiconductor layer SEL1 may be located on the buffer layer 121.

The circuit layer 120 may include light emitting pixel drivers EPD electrically connected to the light emitting elements LE of the element layer 130, respectively.

According to one embodiment, each of the light emitting pixel drivers EPD may include the first transistor T1, the second transistor T2, the third transistor T3, the fourth transistor T4, the fifth transistor T5, the first capacitor C1, and the second capacitor C2.

The first transistor T1 may be electrically connected to the first power line VDL (see FIG. 7) through the power connection transistor TVD.

Each of the first transistor T1, the second transistor T2, the third transistor T3, the fourth transistor T4, the power connection transistor TVD, and the fifth transistor T5 may include a gate electrode, a channel portion overlapping the gate electrode, a first electrode portion connected to one side of the channel portion, and a second electrode portion connected to the other side of the channel portion.

According to one embodiment, the first transistor T1, the second transistor T2, the third transistor T3, and the fourth transistor T4 may be N-type MOSFETs, and the power connection transistor TVD and the fifth transistor T5 may be P-type MOSFETs.

That is, the channel portion, the first electrode portion, and the second electrode portion of each of the first transistor T1, the second transistor T2, the third transistor T3, and the fourth transistor T4 may be located in the second semiconductor layer SEL2, and the channel portion, the first electrode portion, and the second electrode portion of each of the power connection transistor TVD and the fifth transistor T5 may be located in the first semiconductor layer SEL1.

The channel portion of each of the power connection transistor TVD and the fifth transistor T5 may overlap the light blocking portion LBP located on the substrate 110. The buffer layer 121 may cover the light blocking portion LBP.

The fifth transistor T5 may include the channel portion CH5 located in the first semiconductor layer SEL1, the first electrode E15 located in the first semiconductor layer SEL1 and connected to one side of the channel portion CH5, the second electrode E25 located in the first semiconductor layer SEL1 and connected to the other side of the channel portion CH5, and the gate electrode G5 located in the first gate insulating layer GCDL1 and overlapping the channel portion CH5.

The first semiconductor layer SEL1 may include a silicon semiconductor material such as polysilicon or amorphous silicon.

The power connection transistor TVD is a P-type MOSFET similarly to the fifth transistor T5, and any redundant description will be omitted below.

The first transistor T1 and the second transistor T2 may include channel portions CH1 and CH2 located in the second semiconductor layer SEL2, first electrodes E11 and E12 located in the second semiconductor layer SEL2 and connected to one side of the channel portions CH1 and CH2, second electrodes E21 and E22 located in the second semiconductor layer SEL2 and connected to the other sides of the channel portions CH1 and CH2, and gate electrodes G1 and G2 located in the third gate conductive layer GCDL3 and overlapping the channel portions CH1 and CH2, respectively.

The second semiconductor layer SEL2 may include an oxide semiconductor material.

The first gate conductive layer GCDL1 may include a first capacitor electrode CAE1 and a second capacitor electrode CAE2 that are spaced apart from each other.

The second gate conductive layer GCDL2 may include a third capacitor electrode CAE3 overlapping the first capacitor electrode CAE1 and the second capacitor electrode CAE2.

The top surface of the channel portion CH1 of the first transistor T1 may face the gate electrode G1.

Further, the bottom surface of the channel portion CH1 of the first transistor T1 may face the third capacitor electrode CAE3. The third capacitor electrode CAE3 may be electrically connected to the second electrode E21 of the first transistor T1 through a second node connection electrode NCE2.

That is, the third capacitor electrode CAE3 may be the additional electrode of the first transistor T1.

The first electrode E12 of the second transistor T2 may be electrically connected to the data line DL through a data connection electrode DCE.

The data connection electrode DCE may be located in the first source-drain conductive layer SDCDL1 and may be electrically connected to the first electrode E12 of the second transistor T2 through a data connection hole DCH.

The data connection hole DCH may extend through the second interlayer insulating layer 126 and the third gate insulating layer 125.

The data line DL may be located in the second source-drain conductive layer SDCDL2, and may be electrically connected to the data connection electrode DCE through a data connection additional hole DCAH penetrating the first planarization layer 127.

The first source-drain conductive layer SDCDL1 may include a first node connection electrode NCE1, a second node connection electrode NCE2, the data connection electrode DCE, and a first anode connection electrode ANCE1.

The second source-drain conductive layer SDCDL2 may include a second anode connection electrode ANCE2, the data line DL, and an additional power line VDAL.

The second electrode E22 of the second transistor T2 may be electrically connected to the first capacitor electrode CAE1 and the gate electrode G1 of the first transistor T1 through the first node connection electrode NCE1.

The first node connection electrode NCE1 may be electrically connected to the gate electrode G1 of the first transistor T1 through a first node connection hole NCH1, electrically connected to the first capacitor electrode CAE1 through a second node connection hole NCH2, and electrically connected to the second electrode E22 of the second transistor T2 through a third node connection hole NCH3.

The second electrode E21 of the first transistor T1 may be electrically connected to the third capacitor electrode CAE3 and the first electrode E15 of the fifth transistor T5 through the second node connection electrode NCE2.

The second node connection electrode NCE2 may be electrically connected to the second electrode E21 of the first transistor T1 through a fourth node connection hole NCH4, electrically connected to the third capacitor electrode CAE3 through a fifth node connection hole NCH5, and electrically connected to the first electrode E15 of the fifth transistor T5 through a sixth node connection hole NCH6.

The second capacitor electrode CAE2 may be located in the second gate conductive layer on the second gate insulating layer 123.

Since the first capacitor electrode CAE1 is electrically connected to the gate electrode G1 of the first transistor T1, and the third capacitor electrode CAE3 is electrically connected to the second electrode E21 of the first transistor T1, the first capacitor C1 may be formed in a region where the first capacitor electrode CAE1 and the third capacitor electrode CAE3 overlap each other.

The first power line VDL (see FIG. 7) may be located in the first gate conductive layer GCDL1.

The second capacitor electrode CAE2 may be a part of the first power line VDL (see FIG. 7).

The additional power line VDAL may extend in a direction intersecting the first power line VDL, and may be electrically connected to the first power line VDL.

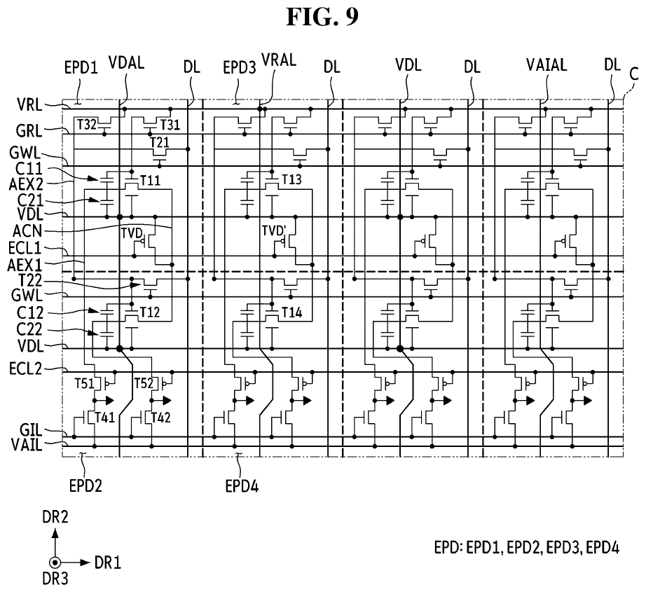

For example, as illustrated in FIG. 9, the first power line VDL may extend in the first direction DR1, and the additional power line VDAL may extend in the second direction DR2.

Accordingly, the first power ELVDD (see FIG. 7) may be transmitted to the display area DA (see FIG. 3) through a mesh-shaped wire including the first power line VDL and the additional power line VDAL.

As illustrated in FIG. 8, according to one embodiment, the second capacitor electrode CAE2 may be a part of the first power line VDL (see FIG. 7) that transmits the first power ELVDD (see FIG. 7).

Since the third capacitor electrode CAE3 is electrically connected to the second electrode E21 of the first transistor T1 through the second node connection electrode NCE2, the second capacitor C2 may be formed in a region where the second capacitor electrode CAE2 and the third capacitor electrode CAE3 overlap each other.

The second electrode E25 of the fifth transistor T5 may be electrically connected to the anode electrode 131 of the light emitting element LE through the first anode connection electrode ANCE1 and the second anode connection electrode ANCE2.

The first anode connection electrode ANCE1 may be electrically connected to the second electrode E25 of the fifth transistor T5 through a first anode connection hole ANCH1.

The first anode connection hole ANCH1 may extend through the second interlayer insulating layer 126, the third gate insulating layer 125, the first interlayer insulating layer 124, the second gate insulating layer 123, and the first gate insulating layer 122.

The second anode connection electrode ANCE2 may be electrically connected to the first anode connection electrode ANCE1 through a second anode connection hole ANCH2 extending through the first planarization layer 127.

The anode electrode 131 may be located on the second planarization layer 128, and may be electrically connected to the second anode connection electrode ANCE2 through a third anode connection hole ANCH3.

The element layer 130 may be located on the circuit layer 120, and may include the light emitting elements LE respectively corresponding to the emission areas EA.

Each of the light emitting elements LE may include the anode electrode 131 and a cathode electrode 134 facing each other, and a light emitting layer 133 located between the anode electrode 131 and the cathode electrode 134.

That is, the element layer 130 may include the anode electrode 131 located in the emission areas EA, a pixel defining layer 132 located in the non-emission area NEA and covering the edge of the anode electrode 131, the light emitting layer 133 located on the anode electrode 131, and the cathode electrode 134 located on the light emitting layers 133 and the pixel defining layer 132.

Accordingly, each of the light emitting elements LE may have a structure in which a light emitting layer 133 is located between an anode electrode 131 and a cathode electrode 134.

Alternatively, the element layer 130 may further include a first common layer located between the anode electrode 131 and the light emitting layer 133, and a second common layer located between the light emitting layer 133 and the cathode electrode 134.

The pixel defining layer 132 may include a first pixel defining layer 1321 located on the second planarization layer 128, a second pixel defining layer 1322 located on the first pixel defining layer 1321, and a spacer layer 1323 located on a part of the second pixel defining layer 1322.

For example, the first pixel defining layer 1321 may include a material that blocks or absorbs light.

In this way, light incident on the second semiconductor layer SEL2, and light emitted to the non-emission area NEA may be blocked by the first pixel defining layer 1321. Therefore, the leakage current of the first transistor T1 due to light may be reduced, and light leakage defects may be reduced.

The anode electrode 131 may be located in the emission area EA and may be electrically connected to the light emitting pixel driver EPD. This anode electrode 131 may be referred to as a pixel electrode.

The light emitting layer 133 may include an organic light emitting material that converts electron-hole pairs into light.

The cathode electrode 134 may be located in the display area (see FIG. 3) including the emission areas EA. The cathode electrode 134 may be a part of the second power line VSL (see FIG. 7) that transmits the second power ELVSS (see FIG. 7) or may be electrically connected to the second power line VSL. The cathode electrode 134 may be referred to as a common electrode.

The encapsulation layer 140 may be located on the circuit layer 120 and cover the element layer 130.

For example, the encapsulation layer 140 may include a first encapsulation layer located on the element layer 130 and containing an inorganic insulating material, a second encapsulation layer located on the first encapsulation layer, overlapping the element layer 130, and containing an organic insulating material, and a third encapsulation layer located on the first encapsulation layer, covering the second encapsulation layer, and containing an inorganic insulating material.

FIG. 9 is a block diagram showing part C of FIG. 5 according to one embodiment.

FIG. 9 illustrates the arrangement of eight light emitting pixel drivers EPD arranged in a 4×2 matrix form in a part of the display area DA and wires electrically connected to the eight light emitting pixel drivers EPD.

Referring to FIG. 9, the circuit layer 120 (see FIG. 4) of the display device 100 according to one embodiment may include the light emitting pixel drivers EPD that respectively transmit a driving current to the light emitting elements LE (see FIGS. 7 and 8), the first power line VDL that transmits the first power ELVDD (see FIG. 8) to the light emitting pixel drivers EPD and extends in the first direction DR1, and the power connection transistor TVD that is electrically connected between the first power line VDL and the first light emitting pixel driver EPD1 and the second light emitting pixel driver EPD2 adjacent to each other in the second direction DR2 among the light emitting pixel drivers EPD.

According to one embodiment of FIG. 9, the light emitting pixel drivers EPD may further include the third light emitting pixel driver EPD3 and the fourth light emitting pixel driver EPD4 adjacent to the first light emitting pixel driver EPD1 and the second light emitting pixel driver EPD2 in the first direction DR1, respectively.

The circuit layer 120 may further include a power connection transistor TVD′ electrically connected between the first power line VDL and the third light emitting pixel driver EPD3 and the fourth light emitting pixel driver EPD4 adjacent to each other in the second direction DR2.

That is, according to one embodiment of FIG. 9, two light emitting pixel drivers EPD1 and EPD2 or EPD3 and EPD4 adjacent to each other in the second direction DR2 may share one power connection transistor TVD or TVD′.

The first light emitting pixel driver EPD1 may include a first transistor T11, a second transistor T21, a third transistor T31, a fourth transistor T41, a fifth transistor T51, a first capacitor C11, and a second capacitor C21.

Similarly, the second light emitting pixel driver EPD may include a first transistor T12, a second transistor T22, a third transistor T32, a fourth transistor T42, a fifth transistor T52, a first capacitor C12, and a second capacitor C22.

The power connection transistor TVD may be electrically connected to the first transistor T11 of the first light emitting pixel driver EPD1 and the first transistor T12 of the second light emitting pixel driver EPD2.

According to one embodiment, the circuit layer 120 may further include an auxiliary connection portion ACN extending in the second direction DR2.

The power connection transistor TVD may be electrically connected to the first transistor T11 of the first light emitting pixel driver EPD1 and the first transistor T12 of the second light emitting pixel driver EPD2 through the auxiliary connection portion ACN.

The gate electrodes of the second transistors T21 and T22 may be electrically connected to the scan write line GWL.

The gate electrodes of the third transistors T31 and T32 may be electrically connected to the reset control line GRL. The first electrodes of the third transistors T31 and T32 may be electrically connected to the reference voltage line VRL.

The gate electrodes of the fourth transistors T41 and T42 may be electrically connected to the initialization control line GIL. The first electrodes of the fourth transistors T41 and T42 may be electrically connected to the initialization voltage line VAIL.

The gate electrode of the power connection transistor TVD may be electrically connected to the first emission control line ECL1. The first electrode of the power connection transistor TVD may be electrically connected to the first power connection line VDL.

The gate electrodes of the fifth transistors T51 and T52 may be electrically connected to the second emission control line ECL2.

According to one embodiment, each of the scan write line GWL, the reference voltage line VRL, the reset control line GRL, the first emission control line ECL1, the second emission control line ECL2, the initialization control line GIL, and the initialization voltage line VAIL may extend in the first direction DR1.

Each of the light emitting pixel drivers EPD may intersect the scan write line GWL and the first power line VDL.

According to one embodiment, some of the reference voltage line VRL, the reset control line GRL, the first emission control line ECL1, the second emission control line ECL2, the initialization control line GIL, and the initialization voltage line VAIL may intersect the first light emitting pixel driver EPD1, and some others may intersect the second light emitting pixel driver EPD2.

According to one embodiment, the reference voltage line VRL, the reset control line GRL, and the first emission control line ECL1 may intersect the first light emitting pixel driver EPD1. Further, the second emission control line ECL2, the initialization control line GIL, and the initialization voltage line VAIL may intersect the second light emitting pixel driver EPD2.

According to one embodiment, the power connection transistor TVD may be located adjacent to the boundary between the first light emitting pixel driver EPD1 and the second light emitting pixel driver EPD2 in the second direction DR2. For example, the power connection transistor TVD may be located in the first light emitting pixel driver EPD1.

The fifth transistor T51 of the first light emitting pixel driver EPD1 and the fifth transistor T52 of the second light emitting pixel driver EPD2 may be electrically connected to the second emission control line ECL2 intersecting the second light emitting pixel driver EPD2.

According to one embodiment, the second emission control line ECL2 extends in the first direction DR1, so that the fifth transistor T51 of the first light emitting pixel driver EPD1 may be located adjacent to the fifth transistor T52 of the second light emitting pixel driver EPD2 in the first direction DR1.

According to one embodiment, the first electrode of the fifth transistor T51 of the first light emitting pixel driver EPD1 may be electrically connected to the first transistor T11 of the first light emitting pixel driver EPD1 through a first extension portion AEX1 extending in the second direction DR2.

According to one embodiment, the circuit layer 120 may further include the additional power line VDAL that extends in the second direction DR2 and transmits the first power ELVDD, the reference voltage additional line VRAL that extends in the second direction DR2 and transmits the reference voltage VREF, and the initialization voltage additional line VAIAL that extends in the second direction DR2 and transmits the initialization voltage VAINT.

The additional power line VDAL may extend in the second direction DR2 intersecting the first power line VDL, and may be electrically connected to the first power line VDL. Accordingly, the first power ELVDD may be relatively evenly transmitted to the display area DA through a mesh-shaped wire including the first power supply line VDL and the additional power line VDAL.

The reference voltage additional line VRAL may extend in the second direction DR2 intersecting the reference voltage line VRL and may be electrically connected to the reference voltage line VRL. Accordingly, the reference voltage VREF may be relatively evenly transmitted to the display area DA through a mesh-shaped wire including the reference voltage line VRL and the reference voltage additional line VRAL.

The initialization voltage additional line VAIAL may extend in the second direction DR2 intersecting the initialization voltage line VAIL and may be electrically connected to the initialization voltage line VAIL. Accordingly, the initialization voltage VAINT may be relatively evenly transmitted to the display area DA through a mesh-shaped wire including the initialization voltage line VAIL and the initialization voltage additional line VAIAL.

The third transistor T31 of the first light emitting pixel driver EPD1 and the third transistor T32 of the second light emitting pixel driver EPD2 may be electrically connected to the reset control line GRL and the reference voltage line VRL intersecting the first light emitting pixel driver EPD1.

Since each of the reference voltage line VRL and the reset control line GRL extends in the first direction DR1, the third transistor T32 of the second light emitting pixel driver EPD2 may be located adjacent to the third transistor T31 of the first light emitting pixel driver EPD1 in the first direction DR1.

The fourth transistor T41 of the first light emitting pixel driver EPD1 and the fourth transistor T42 of the second light emitting pixel driver EPD2 may be electrically connected to the initialization control line GIL and the initialization voltage line VAIL intersecting the second light emitting pixel driver EPD2.

Since each of the initialization voltage line VAIL and the initialization control line GIL extends in the first direction DR1, the fourth transistor T41 of the first light emitting pixel driver EPD1 may be located adjacent to the fourth transistor T42 of the second light emitting pixel driver EPD2 in the first direction DR1.

In this way, when the light emitting pixel drivers EPD are arranged in a N×M matrix form in the display area DA, the number of each of the reference voltage line VRL, the reset control line GRL, the first emission control line ECL1, the second emission control line ECL2, the initialization control line GIL, and the initialization voltage line VAIL that are arranged in the display area DA may be reduced to ½ of M. Therefore, the width of the area consumed for arranging various wires is reduced, so that the width of the light emitting pixel drivers EPD may be reduced, which may be advantageous for achieving high resolution of the display device 100.

FIG. 10 is an exploded perspective view of an electronic device according to one embodiment.

The electronic device 10 of one embodiment illustrated in FIG. 10 is substantially the same as or similar to the display device of one embodiment illustrated in FIG. 2, except that at least one optical device 19 is further included and that the display area DA of the display device 100 includes a main display area MDA and at least one sub-display area SBDA, so that redundant description will be omitted below.

The electronic device 10 of one embodiment illustrated in FIG. 10 may include at least one optical device 19 that is located under the display device 100 and overlaps the display area DA. At least one optical device 19 may include a proximity sensor, an illumination sensor, an iris sensor, and a second camera sensor.

The proximity sensor, the illumination sensor, the iris sensor, and the second camera sensor may be located on the top surface of the main circuit board 14 and in a light transmission hole SH of the bracket 13.

The proximity sensor is a sensor for detecting an object approaching the front surface of the electronic device 10. The proximity sensor may include a light source that outputs light and a light receiver that receives light reflected by an object. The proximity sensor may generate a sensing signal corresponding to the amount of light reflected by the object, and presence or absence of an object near the front surface of the electronic device 10 may be determined based on the sensing signal of the proximity sensor.

The illuminance sensor is a sensor for detecting the brightness of the front surface of the electronic device 10. The illuminance sensor may include a resistor whose resistance value changes according to the brightness of the incident light.

The iris sensor is a sensor for imaging the user's iris. It can be verified whether the user is a pre-registered user based on whether the image captured by the iris sensor is the same as an iris image previously stored in a memory.

The second camera sensor may process an image frame of a still image or video obtained by the image sensor and output it to the main processor 15. The second camera sensor may be a complementary metal-oxide-semiconductor (CMOS) image sensor or a charge-coupled device (CCD) sensor. The number of pixels of the second camera sensor may be smaller than the number of pixels of the camera device 16, and the size of the second camera sensor may be smaller than the size of the camera device 16.

The display area DA may include the main display area MDA located in most of the display area DA, and the at least one sub-display area SBDA surrounded by the main display area MDA.

The light transmission hole SH into which at least one optical device 18 is inserted may be further formed in the bracket 13.

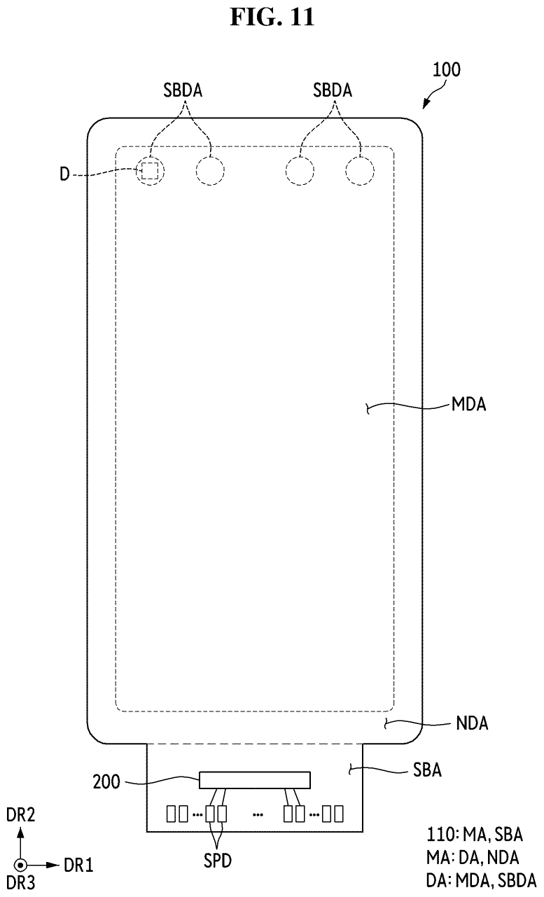

FIG. 11 is a plan view illustrating the display device of FIG. 10.

As illustrated in FIG. 11, the display device 100 of the electronic device 10 according to one embodiment of FIG. 10 may include the main region MA corresponding to the display surface, and the sub-region SBA connected to a part of one side of the main region MA.

In the sub-region SBA, the display driving circuit 200 provided as an integrated circuit (IC) chip may be mounted, and pads SPD to which the display circuit board 300 is bonded may be located.

The main region MA may include the display area DA from which light for displaying an image is emitted, and the non-display area NDA located around the display area DA.

The display area DA may include the main display area MDA located in most of the display area DA, and the at least one sub-display area SBDA surrounded by the main display area MDA.

The at least one sub-display area SBDA may overlap the at least one optical device 18.

FIG. 11 illustrates a case where the display area DA includes four sub-display areas SBDA arranged in the first direction DR1, but this is only an example. That is, according to one embodiment, if the condition in which at least a part of the display area DA is the sub-display area SBDA is satisfied, the number, shape, and arrangement of the sub-display areas SBDA may be changed as desired.

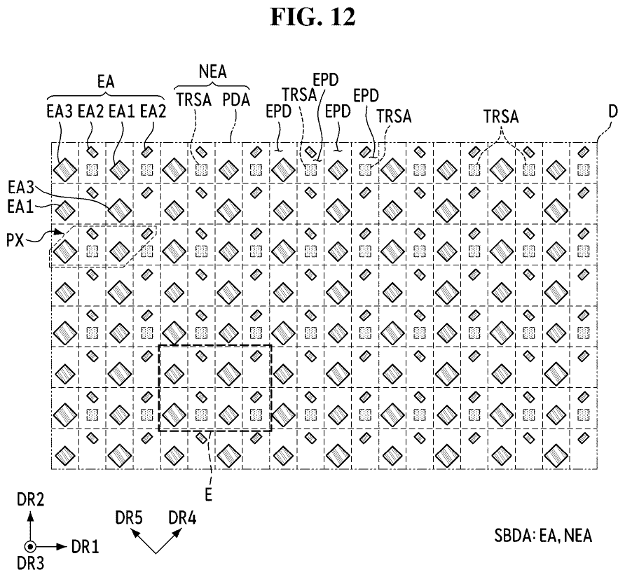

FIG. 12 is a schematic diagram illustrating part D of FIG. 10.

One embodiment of FIG. 12 is substantially the same as or similar to one embodiment of FIG. 5 except that the display area DA of the display device 100 includes a light transmitting area TRSA that transmits light, so that redundant description will be omitted below.

According to one embodiment of FIG. 12, at least one sub-display area SBDA of the display area DA includes the emission areas EA from which light is emitted, and the non-emission area NEA that is located between the emission areas EA and from which light is not emitted.

Further, the non-emission area NEA may include the light transmitting areas TRSA that transmit light.

The other part of the non-emission area NEA except the light transmitting areas TRSA may be a pixel defining area PDA that blocks the incidence or emission of light.

In this way, according to one embodiment, at least one sub-display area SBDA overlapping at least one optical device 18 includes the light transmitting areas TRSA, and a light path that passes through the display device 100 may be formed relatively easily by the light transmitting areas TRSA.

Since at least one optical device 18 overlaps at least one sub-display area SBDA including the light transmitting areas TRSA, even if at least one optical device 18 is located under the display device 100, the light sensing operation may be implemented.

In addition, at least one sub-display area SBDA includes both the light transmitting areas TRSA and the emission areas EA, so that deterioration of display quality and aesthetics of the display device 100 due to at least one optical device 18 may be prevented.

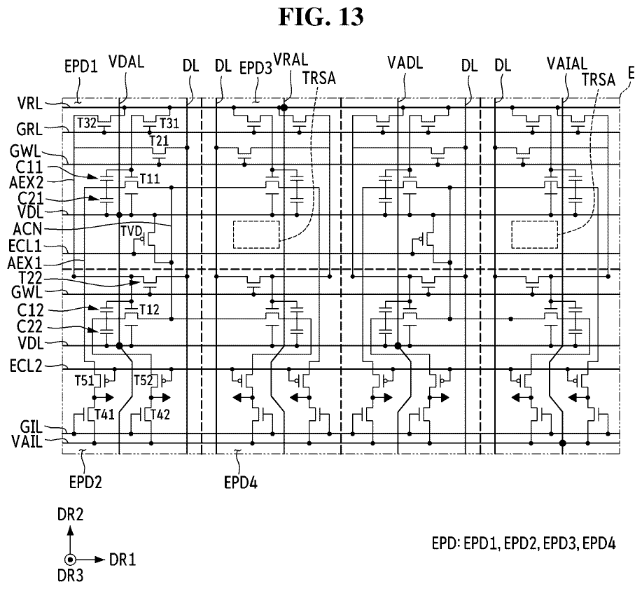

FIG. 13 is a block diagram showing part E of FIG. 12.

FIG. 13 illustrates the arrangement of eight light emitting pixel drivers EPD arranged in a 4×2 matrix form in a part of at least one sub-display area SBDA and wires electrically connected to the eight light emitting pixel drivers EPD.

The display device 100 of one embodiment illustrated in FIG. 13 is substantially the same as or similar to the embodiment of FIG. 9, except that four light emitting pixel drivers EPD1, EPD2, EPD3, and EPD4 adjacent to each other in the first direction DR1 and the second direction DR2 among the light emitting pixel drivers EPD share one power connection transistor TVD, so that redundant description will be omitted below.

As illustrated in FIG. 13, according to one embodiment, the light emitting pixel drivers EPD may include the first light emitting pixel driver EPD1 and the second light emitting pixel driver EPD2 adjacent to each other in the second direction DR2, and the third light emitting pixel driver EPD3 and the fourth light emitting pixel driver EPD4 respectively adjacent to the first light emitting pixel driver EPD1 and the second light emitting pixel driver EPD2 in the first direction DR1.

The power connection transistor TVD electrically connected to the first light emitting pixel driver EPD1 and the second light emitting pixel driver EPD2 may be further electrically connected to the third light emitting pixel driver EPD3 and the fourth light emitting pixel driver EPD4.

That is, one power connection transistor TVD may be electrically connected between the first power line VDL and the four light emitting pixel drivers EPD1, EPD2, EPD3, and EPD4 arranged in a 2×2 array.

Unlike the embodiment of FIG. 9, according to the embodiment of FIG. 13, a separate power connection transistor TVD′ (see FIG. 9) electrically connected to the third light emitting pixel driver EPD3 and the fourth light emitting pixel driver EPD4 is eliminated, so that the light transmitting area TRSA that transmits light may be relatively easily located, instead of the separate power connection transistor TVD′ (see FIG. 9).

That is, according to one embodiment of FIG. 13, the power connection transistor TVD may be located adjacent to the boundary between the first light emitting pixel driver EPD1 and the second light emitting pixel driver EPD2 in the second direction DR2.

The light transmitting area TRSA may be located adjacent to the boundary between the third light emitting pixel driver EPD3 and the fourth light emitting pixel driver EPD4 in the second direction DR2, and may be located adjacent to the power connection transistor TVD in the first direction DR1.

The power connection transistor TVD may be electrically connected to the first light emitting pixel driver EPD1, the second light emitting pixel driver EPD2, the third light emitting pixel driver EPD3, and the fourth light emitting pixel driver EPD4 through the auxiliary connection portion ACN extending in the second direction DR2.

According to one embodiment of FIG. 13, the auxiliary connection portion ACN may be located between the power connection transistor TVD and the light transmitting area TRSA in the first direction DR1.

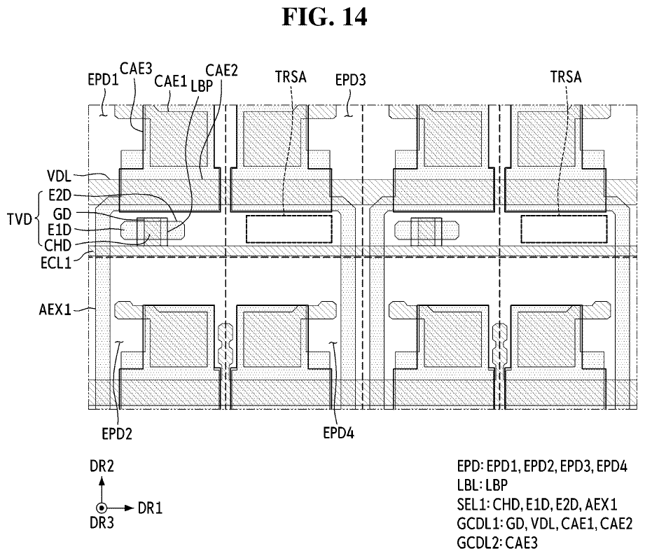

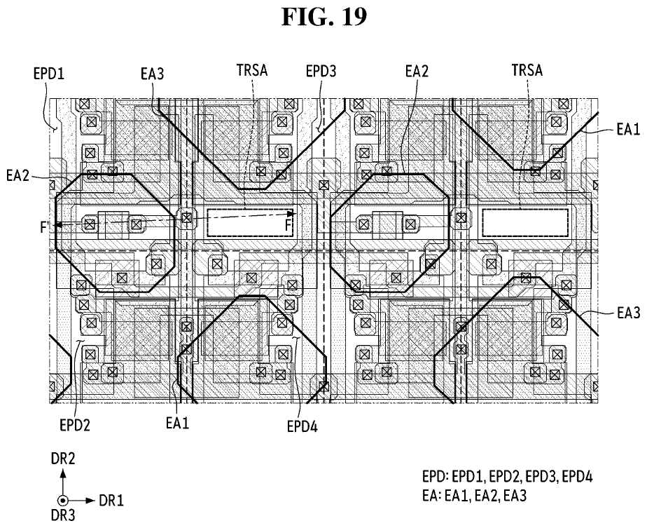

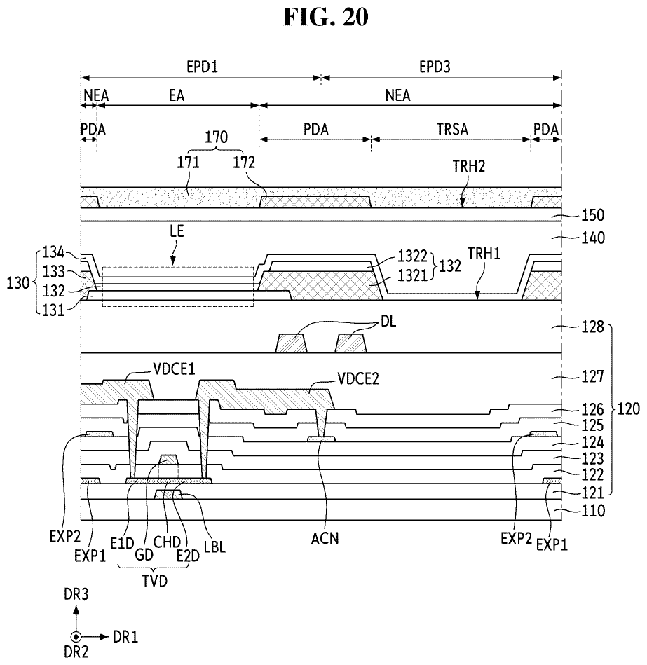

FIGS. 14, 15, 16, 17, 18, and 19 are plan views showing at least a partial view of part E of FIG. 12 according to one embodiment. FIG. 20 is a cross-sectional view taken along line F-F′ of FIG. 19.

FIGS. 14, 15, 16, 17 and 18 illustrate the first transistors T1 of eight light emitting pixel drivers arranged in a 4×2 array in a part of at least one sub-display area SBDA, and two power connection transistors TVD electrically connected to the first transistors T1. Further, FIG. 19 illustrates the emission areas EA and the light transmitting areas TRSA located in a part of at least one sub-display area SBDA.

FIG. 14 illustrates the light blocking layer LBL, the first semiconductor layer SEL1, the first gate conductive layer GCDL1, and the second gate conductive layer GCDL2.

As shown in FIG. 14, the power connection transistor TVD may be located adjacent to the boundary between the first light emitting pixel driver EPD1 and the second light emitting pixel driver EPD2 adjacent to each other in the second direction DR2.

For example, the power connection transistor TVD may be located in the first light emitting pixel driver EPD1.

The third light emitting pixel driver EPD3 and the fourth light emitting pixel driver EPD4 are adjacent to the first light emitting pixel driver EPD1 and the second light emitting pixel driver EPD2 in the first direction DR1, respectively.

According to one embodiment, the power connection transistor TVD located adjacent to the boundary between the first light emitting pixel driver EPD1 and the second light emitting pixel driver EPD2 may be electrically connected to the third light emitting pixel driver EPD3 and the fourth light emitting pixel driver EPD4.

Accordingly, the light transmitting area TRSA may be located, instead of the power connection transistor TVD, in some areas adjacent to the boundary between the third light emitting pixel driver EPD3 and the fourth light emitting pixel driver EPD4.

The light transmitting area TRSA that transmits light does not overlap the light blocking layer LBL, the first semiconductor layer SEL1, the first gate conductive layer GCDL1, and the second gate conductive layer GCDL2 in the third direction DR3 in order to reduce light loss.

The power connection transistor TVD may include a gate electrode GD, a channel portion CHD overlapping the gate electrode GD, a first electrode E1D connected to one side of the channel portion CHD, and a second electrode E2D connected to the other side of the channel portion CHD.

The channel portion CHD of the power connection transistor TVD may overlap the light blocking portion LBP.

The light blocking portion LBP may be located in the light blocking layer LBL on the substrate 110 (see FIG. 20).

The channel region CHD, the first electrode EID, and the second electrode E2D of the power connection transistor TVD may be located in the first semiconductor layer SEL1.

The gate electrode GD of the power connection transistor TVD may be located in the first gate conductive layer GCDL1.

The first emission control line ECL1 electrically connected to the gate electrode GD of the power connection transistor TVD may be located in the first gate conductive layer GCDL1. For example, the gate electrode GD of the power connection transistor TVD may be a portion of the first emission control line ECL1 that overlaps the first semiconductor layer SEL1.

The first semiconductor layer SEL1 may further include the first extension portion AEX1 extending in the second direction DR2.

The fifth transistor T51 (see FIG. 13) of the first light emitting pixel driver EPD1 may be electrically connected to the first transistor T11 (see FIG. 13) of the first light emitting pixel driver EPD1 through the first extension portion AEX1.

The first gate conductive layer GCDL1 may include the first capacitor electrode CAE1 and the second capacitor electrode CAE2 spaced apart from each other, and the first power line VDL extending in the first direction DR1.

The second capacitor electrode CAE2 may be a part of the first power line VDL.

The second gate conductive layer GCDL2 may include the third capacitor electrode CAE3 overlapping the first capacitor electrode CAE1 and the second capacitor electrode CAE2.

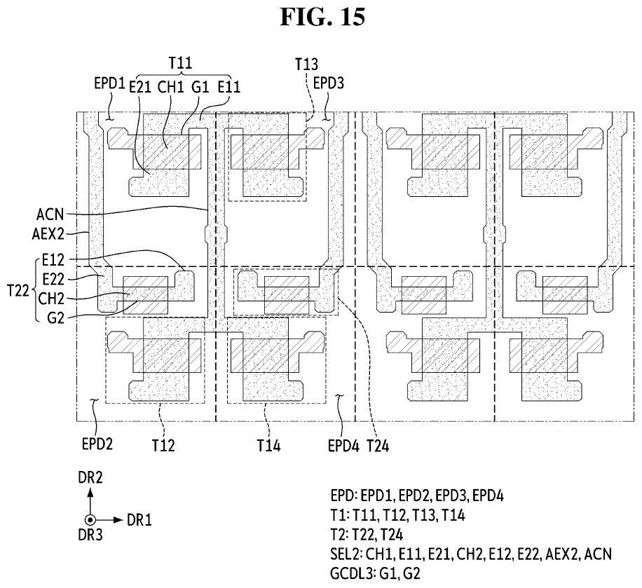

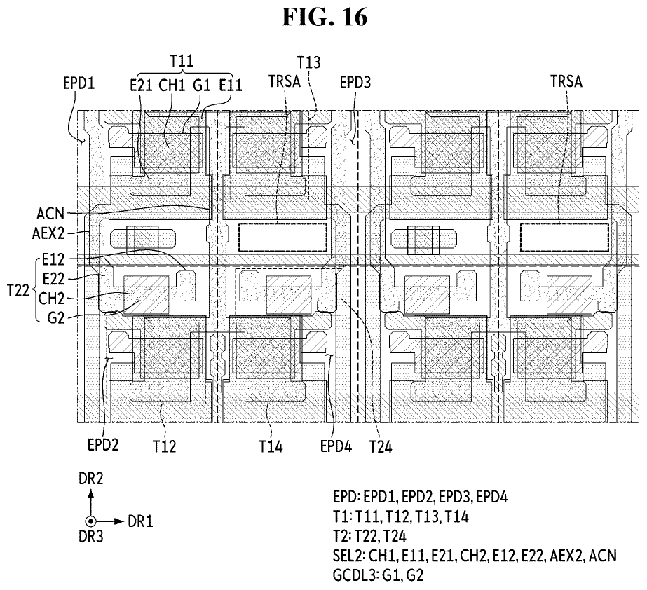

FIG. 15 illustrates the second semiconductor layer SEL2 and the third gate conductive layer GCDL3, and FIG. 16 illustrates the light blocking layer LBL, the first semiconductor layer SEL1, the first gate conductive layer GCDL1, the second gate conductive layer GCDL2, the second semiconductor layer SEL2, and the third gate conductive layer GCDL3.

As illustrated in FIGS. 15 and 16, the first transistor T1 of each light emitting pixel driver EPD may include the gate electrode G1, the channel portion CH1 overlapping the gate electrode G1, the first electrode E11 connected to one side of the channel portion CH1, and the second electrode E21 connected to the other side of the channel portion CH1.

The second transistor T2 of each light emitting pixel driver EPD may include the gate electrode G2, the channel portion CH2 overlapping the gate electrode G2, the first electrode E12 connected to one side of the channel portion CH2, and the second electrode E22 connected to the other side of the channel portion CH2.

The channel portion CH1, the first electrode E11, and the second electrode E21 of the first transistor T1, and the channel portion CH2, the first electrode E12, and the second electrode E22 of the second transistor T2 may be located in the second semiconductor layer SEL2.

The gate electrode G1 of the first transistor T1 and the gate electrode G2 of the second transistor T2 may be located in the third gate conductive layer GCDL3.

The second semiconductor layer SEL2 may include a second extension portion AEX2 extending in the second direction DR2.

The second transistor T22 (see FIG. 13) of the second light emitting pixel driver EPD2 and the first transistor T21 of the second light emitting pixel driver EPD2 may be electrically connected to a third transistor T23 (see FIG. 13) of the second light emitting pixel driver EPD2 through the second extension portion AEX2.

The second semiconductor layer SEL2 may further include the auxiliary connection portion ACN extending in the second direction DR2.

The auxiliary connection portion ACN may be adjacent to the boundary between the first light emitting pixel driver EPD1 and the third light emitting pixel driver EPD3 in the first direction DR1 and the boundary between the second light emitting pixel driver EPD2 and the fourth light emitting pixel driver EPD4 in the first direction DR1, and may extend in the second direction DR2.

According to one embodiment, the second semiconductor layer SEL2 of the first light emitting pixel driver EPD1 may be symmetrical with the second semiconductor layer SEL2 of the third light emitting pixel driver EPD3 with respect to the boundary between the first light emitting pixel driver EPD1 and the third light emitting pixel driver EPD3.

In addition, the second semiconductor layer SEL2 of the second light emitting pixel driver EPD2 may be symmetrical with the second semiconductor layer SEL2 of the fourth light emitting pixel driver EPD4 with respect to the boundary between the second light emitting pixel driver EPD2 and the fourth light emitting pixel driver EPD4.

Accordingly, the first electrode E11 of each of the first transistors T11, T12, T13, and T14 of the first light emitting pixel driver EPD1, the second light emitting pixel driver EPD2, the third light emitting pixel driver EPD3, and the fourth light emitting pixel driver EPD4 may be connected to the auxiliary connection portion ACN.

The light transmitting area TRSA that transmits light does not overlap the second semiconductor layer SEL2 and the third gate conductive layer GCDL3 in the third direction DR3.

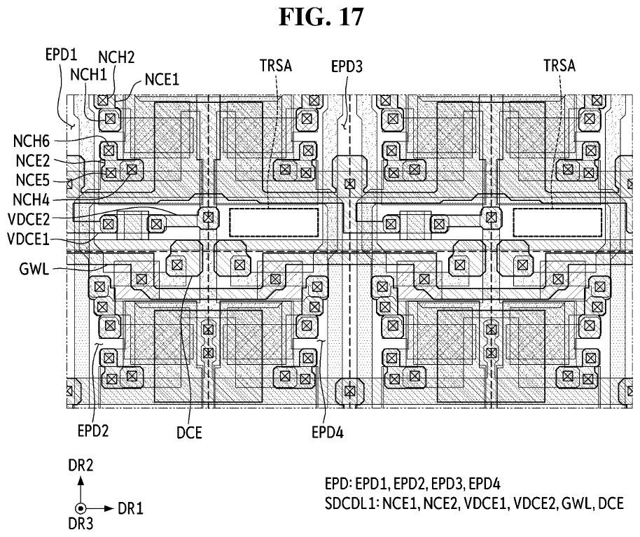

As illustrated in FIG. 17, the first source-drain conductive layer SDCDL1 may include the first node connection electrode NCE1, the second node connection electrode NCE2, a first power connection electrode VDCE1, a second power connection electrode VDCE2, the scan write line GWL, and the data connection electrode DCE.

The first node connection electrode NCE1 may be electrically connected to the gate electrode G1 of the first transistor T1 through the first node connection hole NCH1, and may be electrically connected to the first capacitor electrode CAE1 through the second node connection hole NCH2.

The second node connection electrode NCE2 may be electrically connected to the second electrode E21 of the first transistor T1 through the fourth node connection hole NCH4, electrically connected to the third capacitor electrode CAE3 through the fifth node connection hole NCH5, and electrically connected to the first extension portion AEX1 through the sixth node connection hole NCH6.

As illustrated in FIGS. 17 and 20, the first electrode E1D (see FIG. 14) of the power connection transistor TVD (see FIG. 14) may be electrically connected to the first power line VDL (see FIG. 14) through the first power connection electrode VDCE1.

The second electrode E2D (see FIG. 14) of the power connection transistor TVD (see FIG. 14) may be electrically connected to the auxiliary connection portion ACN through the second power connection electrode VDCE2.

As illustrated in FIG. 17, the scan write line GWL may extend in the first direction DR1.

The data connection electrode DCE may be electrically connected to the first electrode E12 (see FIGS. 15 and 16) of the second transistor T2 (see FIGS. 15 and 16).

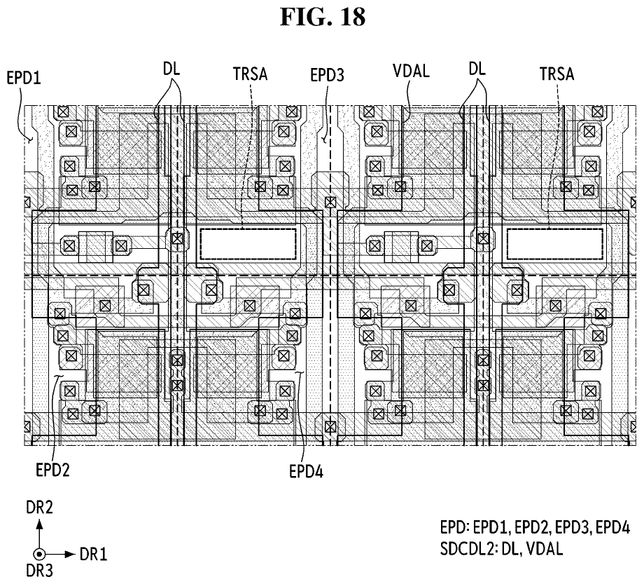

As illustrated in FIG. 18, the second source-drain conductive layer SDCDL2 may include the data line DL and the additional power line VDAL.

Each of the data line DL and the additional power line VDAL may extend in the second direction DR2.

The data line DL may be electrically connected to the data connection electrode DCE.

The additional power line VDAL may be electrically connected to the first power connection electrode VDCE1.

As illustrated in FIGS. 17 and 18, the light transmitting area TRSA that transmits light does not overlap the first source-drain conductive layer SDCDL1 and the second source-drain conductive layer DCDL2 in the third direction DR3.

As illustrated in FIG. 19, the light transmitting areas TRSA may be located in parts of the non-emission area NEA (see FIG. 12) between the emission areas EA.

As illustrated in FIG. 20, the element layer 130 may include the anode electrode 131 located in the emission areas EA, the pixel defining layer 132 located in the non-emission area NEA and covering the edge of the anode electrode 131, the light emitting layer 133 located on the anode electrode 131, and the cathode electrode 134 located on the light emitting layer 133 and the pixel defining layer 132.

The pixel defining layer 132 may include the first pixel defining layer 1321 including a material that blocks or absorbs light, and a first light transmission hole TRH1 formed in the first pixel defining layer 1321 and overlapping the light transmitting area TRSA in the third direction DR3.

The first pixel defining layer 1321 may be located on the circuit layer 120.

The pixel defining layer 132 may further include a second pixel defining layer 1322 located on the first pixel defining layer 1321.

The display device 100 according to one embodiment may further include a color filter layer 170 located on the encapsulation layer 140.

The color filter layer 170 may include a filter portion 171 that is located in the emission areas EA and transmits some of the light that is emitted from the light emitting layer 130, a light blocking portion 172 located in the non-emission area NEA, and a second light transmission hole TRH2 formed in the light blocking portion 172 and overlapping the light transmitting area TRSA in the third direction DR3.

The light transmitting area TRSA does not overlap the light blocking layer LBL, the first semiconductor layer SEL1, the first gate conductive layer GCDL1, the second gate conductive layer GCDL2, the second semiconductor layer SEL2, the third gate conductive layer GCDL3, the first source-drain conductive layer SDCDL1, and the second source-drain conductive layer SDCDL2 of the circuit layer 120 in the third direction DR3, and overlaps the first light transmission hole TRH1 and the second light transmission hole TRH2. Accordingly, a light path that passes through the substrate 110 may be generated by the light transmitting area TRSA.

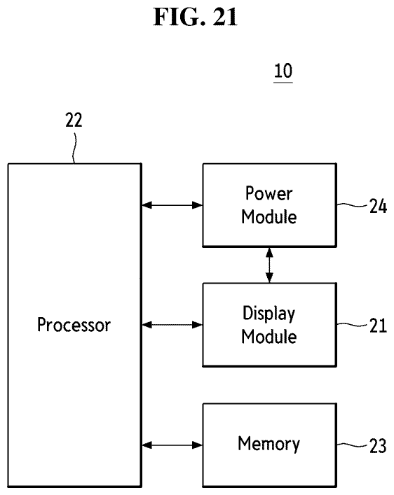

The display device 100 of each embodiment as described above may be applied to various electronic devices 10 (see FIG. 21).

The electronic device 10 (see FIG. 21) according to one embodiment may include the display device 100 described above.

Additionally, the electronic device 10 (see FIG. 21) according to one embodiment may further include a module or device having other additional functions in addition to the display device 100.

FIG. 21 is a block diagram of an electronic device according to one embodiment.

Referring to FIG. 21, the electronic device 10 according to one embodiment may include a display module 21, a processor 22, a memory 23, and a power module 24.

The display module 21 may include the display device 100 that displays an image.

The processor 22 may include at least one of a central processing unit (CPU), an application processor (AP), a graphic processing unit (GPU), a communication processor (CP), an image signal processor (ISP), or a controller.

The memory 23 may store data information required for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 21 described above may be included in the display device according to the embodiments described above. Further, some of individual modules functionally included in one module may be included in the display device and some others may be provided separately from the display device. For example, the display device may include the display module 21, and the processor 22, the memory 23, and the power module 24 may be provided in the form of other devices in the electronic device 21 other than the display device.

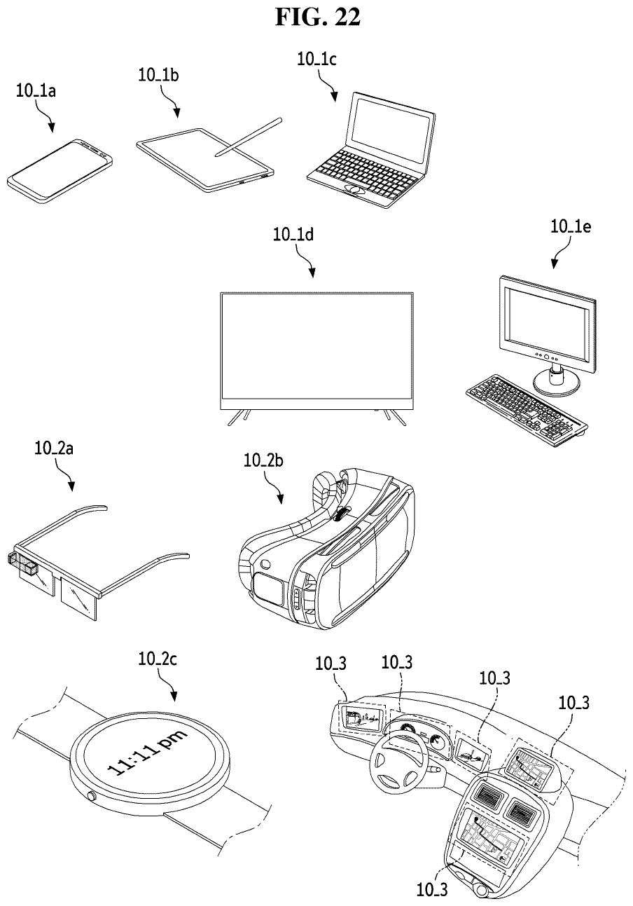

FIG. 22 depicts schematic views of electronic devices according to various embodiments.

Referring to FIG. 22, the electronic devices 10 (see FIG. 21) according to the embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display.

However, the effects of the present disclosure are not restricted to what is explicitly set forth herein. The above and other effects of the present disclosure will become more apparent to one of daily skill in the art to which the present disclosure pertains by referencing the claims.

What is claimed is:

1. A display device comprising:
a substrate comprising a display area in which emission areas are arranged;
a circuit layer located on the substrate; and
an element layer located on the circuit layer,
wherein the element layer comprises light emitting elements arranged in the emission areas, and
the circuit layer comprises:
a first power line that extends in a first direction;
light emitting pixel drivers that receive a first power from the first power line and respectively transmit a driving current to the light emitting elements, the light emitting pixel drivers including a first light emitting pixel driver and a second light emitting pixel driver that are adjacent to each other in a second direction that crosses the first direction;
and
a power connection transistor electrically connected to the first light emitting pixel driver, the second light emitting pixel driver, and the first power line.

2. The display device of claim 1, wherein each of the light emitting pixel drivers comprises a first transistor electrically connected to a first node and generating the driving current, and
the power connection transistor is electrically connected to the first transistor of the first light emitting pixel driver and the first transistor of the second light emitting pixel driver.

3. The display device of claim 2, wherein the circuit layer further comprises an auxiliary connection portion extending in the second direction, and
the power connection transistor is electrically connected to the first transistor of the first light emitting pixel driver and the first transistor of the second light emitting pixel driver through the auxiliary connection portion.

4. The display device of claim 3, wherein the circuit layer comprises:
a first semiconductor layer located on the substrate;
a first gate insulating layer covering the first semiconductor layer;
a first gate conductive layer located on the first gate insulating layer;
a second gate insulating layer covering the first gate conductive layer;
a second gate conductive layer located on the second gate insulating layer;
a first interlayer insulating layer covering the second gate conductive layer; and
a second semiconductor layer located on the first interlayer insulating layer,
wherein each of the first transistor and the power connection transistor comprises a gate electrode, a channel portion overlapping the gate electrode, a first electrode connected to one side of the channel portion, and a second electrode connected to the other side of the channel portion,
the channel portion, the first electrode, and the second electrode of the power connection transistor are located in the first semiconductor layer,
the channel portion, the first electrode and the second electrode of the first transistor are located in the second semiconductor layer, and
the auxiliary connection portion is located in the second semiconductor layer and connected to the first electrode of the first transistor of the first light emitting pixel driver and the first electrode of the first transistor of the second light emitting pixel driver.

5. The display device of claim 4, wherein the light emitting pixel drivers comprise a third light emitting pixel driver and a fourth light emitting pixel driver that are positioned adjacent to the first light emitting pixel driver and the second light emitting pixel driver in the first direction, respectively, and
the power connection transistor is electrically connected to the first transistor of the third light emitting pixel driver and the first transistor of the fourth light emitting pixel driver.

6. The display device of claim 5, wherein with respect to a boundary between the first light emitting pixel driver and the third light emitting pixel driver, the second semiconductor layer of the third light emitting pixel driver is symmetrical with the second semiconductor layer of the first light emitting pixel driver,
with respect to a boundary between the second light emitting pixel driver and the fourth light emitting pixel driver, the second semiconductor layer of the fourth light emitting pixel driver is symmetrical with the second semiconductor layer of the second light emitting pixel driver, and
the auxiliary connection portion is further connected to the first electrode of the first transistor of the third light emitting pixel driver and the first electrode of the first transistor of the fourth light emitting pixel driver.

7. The display device of claim 5, wherein the display area further comprises a non-emission area located between the emission areas,
the non-emission area comprises a light transmitting area that transmits light,
the power connection transistor is adjacent to a boundary between the first light emitting pixel driver and the second light emitting pixel driver in the second direction,
the light transmitting area is adjacent to a boundary between the third light emitting pixel driver and the fourth light emitting pixel driver in the second direction and adjacent to the power connection transistor in the first direction, and
the auxiliary connection portion is located between the power connection transistor and the light transmitting area in the first direction.

8. The display device of claim 7, wherein the element layer comprises:
an anode electrode located in each of the emission areas;
a pixel defining layer located in the non-emission area and covering an edge of the anode electrode;
a light emitting layer located on the anode electrode; and
a cathode electrode located on the pixel defining layer and the light emitting layer,
wherein each of the light emitting elements has a structure in which the light emitting layer is located between the anode electrode and the cathode electrode, and
the pixel defining layer comprises:
a first pixel defining layer containing a material that blocks or absorbs light; and
a first light transmission hole formed in the first pixel defining layer and overlapping the light transmitting area in a third direction perpendicular to the first direction and the second direction.

9. The display device of claim 8, further comprising:
an encapsulation layer covering the element layer; and
a color filter layer located on the encapsulation layer,
wherein the color filter layer comprises:
a filter portion located in each of the emission areas and transmitting some of light emitted from the element layer;
a light blocking portion located in the non-emission area; and
a second light transmission hole formed in the light blocking portion and overlapping the light transmitting area in the third direction.

10. The display device of claim 8, wherein the circuit layer further comprises:
a third gate insulating layer covering the second semiconductor layer;
a third gate conductive layer disposed on the third gate insulating layer;
a second interlayer insulating layer covering the third gate conductive layer;
a first source-drain conductive layer located on the second interlayer insulating layer;
a first planarization layer covering the first source-drain conductive layer;
a second source-drain conductive layer located on the first planarization layer; and
a second planarization layer covering the second source-drain conductive layer,
wherein the first power line is located on the first gate conductive layer,
the auxiliary connection portion is located in the second semiconductor layer,
the first electrode of the power connection transistor is electrically connected to the first power line through a first power connection electrode,
the second electrode of the power connection transistor is electrically connected to the auxiliary connection portion through a second power connection electrode, and
the first power connection electrode and the second power connection electrode are located in the first source-drain conductive layer.

11. The display device of claim 10, wherein the light transmitting area does not overlap the first semiconductor layer, the first gate conductive layer, the second gate conductive layer, the second semiconductor layer, the third gate conductive layer, the first source-drain conductive layer, and the second source-drain conductive layer in the third direction.

12. The display device of claim 3, wherein each of the light emitting pixel drivers comprises:
a second transistor electrically connected between a data line that transmits a data signal and a gate electrode of the first transistor;
a third transistor electrically connected between a reference voltage line that transmits a reference voltage and the gate electrode of the first transistor;
a fourth transistor electrically connected between an initialization voltage line that transmits an initialization voltage and a second node;
a fifth transistor electrically connected between the first node and the second node;
a first capacitor electrically connected between the gate electrode of the first transistor and the first node; and
a second capacitor electrically connected to the first node,
wherein the first node is electrically connected to a second electrode of the first transistor,
the second node is electrically connected to one of the light emitting elements,
a gate electrode of the second transistor is electrically connected to a scan write line that transmits a scan write signal,
a gate electrode of the third transistor is electrically connected to a reset control line that transmits a reset control signal,
a gate electrode of the fourth transistor is electrically connected to an initialization control line that transmits an initialization control signal,
a gate electrode of the power connection transistor is electrically connected to a first emission control line that transmits a first emission control signal,
a gate electrode of the fifth transistor is electrically connected to a second emission control line that transmits a second emission control signal,
each of the reference voltage line, the reset control line, the first emission control line, the second emission control line, the initialization control line, and the initialization voltage line extends in the first direction,
some of the reference voltage line, the reset control line, the first emission control line, the second emission control line, the initialization control line and the initialization voltage line intersect the first light emitting pixel driver, and some others intersect the second light emitting pixel driver.

13. The display device of claim 12, wherein the third transistor of each of the first light emitting pixel driver and the second light emitting pixel driver is electrically connected to a reference voltage line and a reset control line that intersect the first light emitting pixel driver,
the fourth transistor of each of the first light emitting pixel driver and the second light emitting pixel driver is electrically connected to an initialization control line and an initialization voltage line that intersect the second light emitting pixel driver,
the fifth transistor of the first light emitting pixel driver and the fifth transistor of the second light emitting pixel driver are electrically connected to the second emission control line that intersects the second light emitting pixel driver,
the third transistor of the second light emitting pixel driver is adjacent to the third transistor of the first light emitting pixel driver in the first direction,
the fourth transistor of the first light emitting pixel driver is adjacent to the fourth transistor of the second light emitting pixel driver in the first direction, and
the fifth transistor of the first light emitting pixel driver is adjacent to the fifth transistor of the second light emitting pixel driver in the first direction.

14. An electronic device comprising:
a display device displaying an image;
a memory storing an application;
a processor executing the application and transmitting an image data signal and an input control signal to the display device; and
a power module transmitting power to the display device,
wherein the display device comprises:
a substrate comprising a display area in which emission areas are arranged;
a circuit layer located on the substrate; and
an element layer located on the circuit layer,
wherein the element layer comprises light emitting elements arranged in the emission areas, and
the circuit layer comprises:
a first power line that extends in a first direction;
light emitting pixel drivers that receive a first power from the first power line and respectively transmit a driving current to the light emitting elements, the light emitting pixel drivers including a first light emitting pixel driver and a second light emitting pixel driver that are adjacent to each other in a second direction that crosses the first direction;
and
a power connection transistor electrically connected to the first light emitting pixel driver, the second light emitting pixel driver, and the first power line.

15. The electronic device of claim 14, wherein the circuit layer further comprises an auxiliary connection portion extending in the second direction,
each of the light emitting pixel drivers comprises a first transistor electrically connected to a first node and generating the driving current, and
the power connection transistor is electrically connected to the first transistor of the first light emitting pixel driver and the first transistor of the second light emitting pixel driver through the auxiliary connection portion.

16. The electronic device of claim 15, wherein the circuit layer comprises:
a first semiconductor layer located on the substrate;
a first gate insulating layer covering the first semiconductor layer;
a first gate conductive layer located on the first gate insulating layer;
a second gate insulating layer covering the first gate conductive layer;
a second gate conductive layer located on the second gate insulating layer;
a first interlayer insulating layer covering the second gate conductive layer; and
a second semiconductor layer located on the first interlayer insulating layer,
wherein each of the first transistor and the power connection transistor comprises a gate electrode, a channel portion overlapping the gate electrode, a first electrode connected to one side of the channel portion, and a second electrode connected to the other side of the channel portion,
the channel portion, the first electrode, and the second electrode of the power connection transistor are located in the first semiconductor layer,
the channel portion, the first electrode and the second electrode of the first transistor are located in the second semiconductor layer, and
the auxiliary connection portion is located in the second semiconductor layer and connected to the first electrode of the first transistor of the first light emitting pixel driver and the first electrode of the first transistor of the second light emitting pixel driver.

17. The electronic device of claim 16, wherein the light emitting pixel drivers comprise a third light emitting pixel driver and a fourth light emitting pixel driver that are positioned adjacent to the first light emitting pixel driver and the second light emitting pixel driver in the first direction, respectively,
with respect to a boundary between the first light emitting pixel driver and the third light emitting pixel driver, the second semiconductor layer of the third light emitting pixel driver is symmetrical with the second semiconductor layer of the first light emitting pixel driver, and
with respect to a boundary between the second light emitting pixel driver and the fourth light emitting pixel driver, the second semiconductor layer of the fourth light emitting pixel driver is symmetrical with the second semiconductor layer of the second light emitting pixel driver.

18. The electronic device of claim 17, wherein the auxiliary connection portion is further connected to the first electrode of the first transistor of the third light emitting pixel driver and the first electrode of the first transistor of the fourth light emitting pixel driver.

19. The electronic device of claim 17, wherein the display area further comprises a non-emission area located between the emission areas,
the non-emission area comprises a light transmitting area that transmits light,
the power connection transistor is adjacent to a boundary between the first light emitting pixel driver and the second light emitting pixel driver in the second direction,
the light transmitting area is adjacent to a boundary between the third light emitting pixel driver and the fourth light emitting pixel driver in the second direction, and
the auxiliary connection portion is located between the power connection transistor and the light transmitting area in the first direction.

20. The electronic device of claim 19, wherein the display device further comprises:
an encapsulation layer covering the element layer; and
a color filter layer located on the encapsulation layer,
wherein the element layer comprises:
an anode electrode located in each of the emission areas; and
a pixel defining layer located in the non-emission area and covering an edge of the anode electrode,
wherein the pixel defining layer comprises:
a first pixel defining layer containing a material that blocks or absorbs light; and
a first light transmission hole formed in the first pixel defining layer and overlapping the light transmitting area in a third direction perpendicular to the first direction and the second direction,
wherein the color filter layer comprises:
a filter portion located in each of the emission areas and transmitting a part of light emitted from the element layer;
a light blocking portion located in the non-emission area; and
a second light transmission hole formed in the light blocking portion and overlapping the light transmitting area in the third direction.
